(19) United States
(12) Patent Application Publication
(10) Pub. No.: US 2018/0204743 A1
(43) Pub. Date: Jul. 19, 2018

(54) SUBSTRATE TREATMENT METHOD AND SUBSTRATE TREATMENT DEVICE

(71) Applicant: SCREEN Holdings Co., Ltd., Kyoto (JP)

(72) Inventors: Masayuki OTSUJI, Kyoto (JP); Kazuhiro HONSHO, Kyoto (JP)

(21) Appl. No.: 15/744,314

(22) PCT Filed: Jun. 7, 2016
(86) PCT No.: PCT/JP2016/066955

§ 371 Date: Jan. 12, 2018

(30) Foreign Application Priority Data
Aug. 18, 2015 (JP) 2015-161327
Aug. 18, 2015 (JP) 2015-161328

(51) Int. Cl. H01L 21/67; B08B 3/04; B08B 3/08; B08B 3/10; B08B 5/02; B08B 7/00

(52) U.S. Cl. CPC H01L 21/67023; H01L 21/67034; H01L 21/67051; B08B 3/041; B08B 2203/007; B08B 3/10; B08B 5/023; B08B 3/106; B08B 7/0071; B08B 3/08

(57) ABSTRACT

This substrate processing method is a substrate processing method that processes a front surface of a substrate with using a processing liquid, including a mixture replacing step of replacing the processing liquid attached to the front surface of the substrate with a mixture of a first liquid and a second liquid having a higher boiling point than that of the first liquid and a lower surface tension than that of the first liquid, and a mixture removing step of removing the mixture from the front surface of the substrate after the mixture replacing step.

### BACKGROUND OF THE INVENTION

### Technical Field

The present invention relates to a substrate processing method and a substrate processing apparatus that process a front surface of a substrate by using a processing liquid. Examples of substrates to be processed include semiconductor wafers, substrates for liquid crystal display devices, substrates for plasma displays, substrates for FEDs (field emission displays), substrates for optical disks, substrates for magnetic disks, substrates for magneto-optical disks, substrates for photomasks, ceramic substrates, substrates for solar cells, etc.

### Background Art

In a process of manufacturing a semiconductor apparatus, a front surface of a substrate such as a semiconductor wafer is processed with a processing liquid. A single substrate processing type substrate processing apparatus that processes one substrate at a time includes a spin chuck that rotates a substrate while substantially horizontally holding the substrate, and a nozzle arranged to supply a processing liquid to a front surface of the substrate which is rotated by the spin chuck.

In a typical substrate processing process, a chemical liquid is supplied to the substrate held by the spin chuck (chemical liquid processing). After that, water is supplied to the substrate, and thereby, the chemical liquid on the substrate is replaced with the water (rinse processing). After that, a spin drying process arranged to remove the water on the substrate is performed (see Patent Literature 1 and Patent Literature 2). In the spin drying process, by rotating the substrate at high speed, the water attached to the substrate is spun off and removed (dried). Generally, the water is deionized water.

In a case where a minute pattern is formed on the front surface of the substrate, there is a fear that the water entering inside the pattern cannot be removed in the spin drying process, and thereby, there is a fear that drying failure is caused. Thus, there is a proposed method of drying the front surface of the substrate by supplying an organic solvent such as isopropyl alcohol (IPA) to the front surface of the substrate that is after the processing with the water and replacing the water entering into a gap of the pattern on the front surface of the substrate with the organic solvent.

As shown in FIG. 26, in the spin drying process of drying the substrate by high-speed rotation of the substrate, a liquid surface (interface between air and liquid) is formed in the pattern. In this case, surface tension of the liquid acts at a contact position between the liquid surface and the pattern. The surface tension is one of the causes of collapse of the pattern.

As in Patent Literature 2, in a case where a liquid of an organic solvent (hereinafter, simply referred to as “organic solvent”) is supplied to the front surface of the substrate after the rinse processing and before the spin drying process, the organic solvent enters between portions of the pattern. Surface tension of the organic solvent is lower than that of the water which is typical water. Therefore, the problem of the pattern collapse due to the surface tension is eased.

### CITATION LIST

### Patent Literature

Patent Literature 1: Japanese Patent Application Publication No. 2009-212301

Patent Literature 2: Japanese Patent Application Publication No. 9-38595

### SUMMARY OF INVENTION

### Technical Problem

In the rinse processing executed after the chemical liquid processing, particles may sometimes be contained in the water on the substrate. In such a drying method, the particles contained in the water are attached to an upper surface of the substrate again, and as a result, there is a fear that the particles are generated on the front surface (surface to be processed) of the substrate after drying.

Although the low surface tension liquid (organic solvent) is hydrophilic, the replacement performance with the processing liquid (water) is not so high. Therefore, only by supplying the low surface tension liquid, a long time is required for completely replacing the processing liquid on the front surface of the substrate with the low surface tension liquid. As a result of requiring such a long time for replacing with the low surface tension liquid, there is a fear that a drying time of the front surface of the substrate is extended.

Therefore, an object of the present invention is to provide a substrate processing method and a substrate processing apparatus, with which a front surface of a substrate can be dried while reducing or preventing generation of particles.

Another object of the present invention is to provide a substrate processing method and a substrate processing apparatus, with which a processing liquid on a front surface of a substrate can be completely replaced with a low surface tension liquid in a short time, and thereby, the front surface of the substrate can be dried in a short time while reducing collapse of a pattern.

### Solution to Problem

A first aspect of the present invention is to provide a substrate processing method that processes a front surface of a substrate by using a processing liquid, including a mixture replacing step of replacing the processing liquid attached to the front surface of the substrate with a mixture of a first liquid and a second liquid having a higher boiling point than that of the first liquid and a lower surface tension than that of the first liquid, and a mixture removing step of removing the mixture from the front surface of the substrate after the mixture replacing step.

With this method, the processing liquid on the front surface of the substrate is replaced with the mixture, and the mixture comes into contact with the front surface of the substrate. On the front surface of the substrate, while the mixture is evaporated at a gas-liquid-solid interface of the mixture, a liquid removed region is expanded. At the gas-liquid-solid interface, the first liquid having a relatively low boiling point is mainly evaporated. As a result, concentration of the second liquid having a relatively high boiling point and low surface tension is increased. Therefore, in a portion of the mixture around the gas-liquid-solid interface (hereinafter, referred to as “around-interface portion” in the present section), such a concentration gradient that the concentration of the second liquid is increased toward the gas-liquid-solid interface is formed. Due to a concentration difference in the second liquid, inside the around-interface portion of the mixture, Marangoni convection flowing in the direction of separating from the gas-liquid-solid interface is generated.

Thereby, particles contained in the around-interface portion of the mixture receive the Marangoni convection and move in the direction of separating from the gas-liquid-solid interface. Therefore, the particles are taken into a bulk of the mixture. While being taken into the bulk of the mixture, the particles contained in the mixture are then discharged from the front surface of the substrate together with the mixture without appearing at the gas-liquid-solid interface. Thereby, after drying the substrate, the particles do not remain on the front surface of the substrate. Therefore, the entire front surface of the substrate can be dried while reducing or preventing the generation of the particles.

In this preferred embodiment, the above method further includes a substrate holding step of horizontally holding the substrate, the mixture replacing step includes a liquid film forming step of forming a liquid film of the mixture covering an upper surface of the substrate, and the mixture removing step includes a liquid film removed region forming step of forming a liquid film removed region in the liquid film of the mixture, and a liquid film removed region expanding step of expanding the liquid film removed region toward an outer periphery of the substrate.

With this method, the liquid film of the mixture is formed on the upper surface of the substrate held in a horizontal posture. The liquid film removed region is formed in the liquid film of the mixture, and further, the liquid film removed region is expanded to cover the entire substrate.

On the upper surface of the substrate, while the mixture is evaporated at the gas-liquid-solid interface of the liquid film of the mixture, the liquid film removed region is expanded. At the gas-liquid-solid interface, the first liquid having a relatively low boiling point is mainly evaporated. As a result, the concentration of the second liquid having a relatively high boiling point and the low surface tension is increased. Therefore, in the around-interface portion of the liquid film of the mixture, such a concentration gradient that the concentration of the second liquid is increased toward the gas-liquid-solid interface is formed. Due to such a concentration difference in the second liquid, inside the around-interface portion of the liquid film of the mixture, Marangoni convection flowing in the direction of separating from the gas-liquid-solid interface is generated. After the formation of the liquid film removed region, the Marangoni convection continues to be generated until the liquid film removed region covers the entire substrate.

Thereby, particles contained in the around-interface portion of the liquid film of the mixture receive the Marangoni convection and move in the direction of separating from the gas-liquid-solid interface. Therefore, the particles are taken into the liquid film of the mixture. In accordance with the expansion of the liquid film removed region, the gas-liquid-solid interface is moved radially outward of the substrate. However, while the particles are taken into the bulk of the liquid film of the mixture, the liquid film removed region is expanded. The particles are then discharged from the upper surface of the substrate together with the liquid film of the mixture without appearing at the liquid film removed region. Thereby, after drying the substrate, the particles do not remain on the upper surface of the substrate. Therefore, the entire upper surface of the substrate can be dried while reducing or preventing the generation of the particles.

The above method may further include a puddling step of bringing the substrate into a stationary state or rotating the substrate about the rotation axis at a puddle speed in parallel with the liquid film forming step.

With this method, the puddling step is executed in parallel with the liquid film forming step. Thus, thickness of the around-interface portion of the liquid film of the mixture formed on the upper surface of the substrate can be maintained thick. Since the thickness of the around-interface portion of the liquid film of the mixture is large, the Marangoni convection can be stably generated in the around-interface portion.

In the above method, the liquid film removed region forming step may include a gas blowing step of blowing gas to the upper surface of the substrate.

With this method, by blowing the gas to the liquid film of the mixture, part of the mixture contained in the liquid film of the mixture is blown off and removed. Thereby, the liquid film removed region can be easily formed.

The gas may include a high-temperature gas having a higher temperature than an ordinary temperature.

With this method, by supplying the high-temperature gas to the upper surface of the substrate, the evaporation of the first liquid at the gas-liquid-solid interface of the liquid film of the mixture can be facilitated. Thereby, the concentration gradient of the second liquid in the around-interface portion of the liquid film of the mixture can be made radical. Therefore, the Marangoni convection generated in the around-interface portion of the liquid film of the mixture can be further strengthened.

The liquid film removed region expanding step may include a high speed rotating step of rotating the substrate at higher speed than that of the time of the liquid film forming step.

With this method, by strong centrifugal force which is generated by rotating the substrate at high speed, the liquid film removed region can be expanded.

The first liquid may include water, and the second liquid may include ethylene glycol (hereinafter, referred to as “EG”).

With this method, the processing liquid on the front surface of the substrate is replaced with the mixture, and the mixture comes into contact with the front surface of the substrate. On the front surface of the substrate, while the mixture is evaporated at the gas-liquid-solid interface of the mixture, the liquid removed region is expanded. At the gas-liquid-solid interface, the water having a relatively low boiling point is mainly evaporated. As a result, concentration of the EG having a relatively high boiling point and low surface tension is increased. Therefore, in a portion of the mixture around the gas-liquid-solid interface (hereinafter, referred to as “around-interface portion” in the present section), such a concentration gradient that the EG concentration is increased toward the gas-liquid-solid interface is formed. Due to such a concentration difference in the EG, inside the around-interface portion of the mixture, Marangoni convection flowing in the direction of separating from the gas-liquid-solid interface is generated.

Thereby, the particles contained in the around-interface portion of the mixture receive the Marangoni convection and move in the direction of separating from the gas-liquid-solid interface. Therefore, the particles are taken into the bulk of the mixture. While being taken into the bulk of the mixture, the particles contained in the mixture are then discharged from the front surface of the substrate together with the mixture without appearing at the gas-liquid-solid interface. Thereby, after drying the substrate, the particles do not remain on the front surface of the substrate. Therefore, the entire front surface of the substrate can be dried while reducing or preventing the generation of the particles.

A second aspect of the present invention is to provide a substrate processing apparatus including a substrate holding unit that horizontally holds a substrate, a mixture supplying unit that supplies a mixture of a first liquid and a second liquid having a higher boiling point than that of the first liquid and a lower surface tension than that of the first liquid to an upper surface of the substrate, and a controller that controls at least the mixture supplying unit, wherein the controller executes a liquid film forming step of forming a liquid film of the mixture covering the upper surface of the substrate, a liquid film removed region forming step of forming a liquid film removed region in the liquid film of the mixture, and a liquid film removed region expanding step of expanding the liquid film removed region toward an outer periphery of the substrate.

With this arrangement, the liquid film of the mixture is formed on the upper surface of the substrate held in a horizontal posture. The liquid film removed region is formed in the liquid film of the mixture, and further, the liquid film removed region is expanded until it covers the entire substrate.

On the upper surface of the substrate, while the mixture is evaporated at the gas-liquid-solid interface of the liquid film of the mixture, the liquid film removed region is expanded. At the gas-liquid-solid interface, the first liquid having a relatively low boiling point is mainly evaporated. As a result, concentration of the second liquid having a relatively high boiling point and the low surface tension is increased. Therefore, in an around-interface portion of the liquid film of the mixture, such a concentration gradient that the concentration of the second liquid is increased toward the gas-liquid-solid interface is formed. Due to such a concentration difference in the second liquid, inside the around-interface portion of the liquid film of the mixture, Marangoni convection flowing in the direction of separating from the gas-liquid-solid interface is generated. After the formation of the liquid film removed region, the Marangoni convection continues to be generated until the liquid film removed region covers the entire substrate.

Thereby, the particles contained in the around-interface portion of the liquid film of the mixture receive the Marangoni convection and move in the direction of separating from the gas-liquid-solid interface. Therefore, the particles are taken into the liquid film of the mixture. In accordance with the expansion of the liquid film removed region, the gas-liquid-solid interface is moved radially outward of the substrate. However, while the particles are taken into the bulk of the liquid film of the mixture, the liquid film removed region is expanded. The particles are then discharged from the upper surface of the substrate together with the liquid film of the mixture without appearing at the liquid film removed region. Thereby, after drying the substrate, the particles do not remain on the upper surface of the substrate. Therefore, the entire upper surface of the substrate can be dried while reducing or preventing the generation of the particles.

A third aspect of the present invention is to provide a substrate processing method that processes a front surface of a substrate by using a processing liquid, including a mixture forming step of, by supplying a low surface tension liquid having a higher boiling point than that of the processing liquid and a lower surface tension than that of the processing liquid to the front surface of the substrate where the processing liquid remains, forming a mixture of the remaining processing liquid and the low surface tension liquid on the front surface of the substrate, a replacing step of evaporating the processing liquid from the mixture supplied to the front surface of the substrate and replacing at least the mixture on an interface between the mixture and the front surface of the substrate with the low surface tension liquid, and a drying step of removing the low surface tension liquid from the front surface of the substrate and drying the front surface of the substrate.

With this method, the low surface tension liquid is supplied to the front surface of the substrate where the processing liquid remains. Thereby, the processing liquid and the low surface tension liquid are mixed, and the mixture is formed on the front surface of the substrate. Then, the processing liquid having the low boiling point contained in the mixture is evaporated. As a result, the processing liquid on the front surface of the substrate can be completely replaced with the low surface tension liquid.

The mixture is formed by the supply of the low surface tension liquid and the processing liquid contained in the mixture is evaporated, so that only the low surface tension liquid remains. Thus, speed to replace the processing liquid with the low surface tension liquid can be increased. Thereby, the processing liquid on the front surface of the substrate can be completely replaced with the low surface tension liquid in a short time. Therefore, the front surface of the substrate can be dried in a short time while reducing collapse of a pattern.

In the present description, the phrase “the processing liquid remains on the front surface of the substrate” is intended to include a state where the liquid film of the processing liquid is formed on the front surface of the substrate, a state where droplets of the processing liquid exist on the front surface of the substrate, and in addition, a state where no liquid film or droplets exist on the front surface of the substrate but the processing liquid enters the pattern on the front surface of the substrate.

In a preferred embodiment of the present invention, the replacing step includes a mixture heating step of heating the mixture in order to evaporate the processing liquid contained in the mixture.

With this method, the low surface tension liquid is supplied to the front surface of the substrate where the processing liquid remains. Thereby, the processing liquid and the low surface tension liquid are mixed, and the mixture is formed on the front surface of the substrate. By then heating the mixture, the processing liquid having the low boiling point contained in the mixture can be evaporated. Thereby, the processing liquid on the front surface of the substrate can be completely replaced with the low surface tension liquid.

The above method may further include a substrate holding step of horizontally holding the substrate, the mixture forming step may include a step of forming a liquid film of the mixture covering an upper surface of the substrate, and the mixture heating step may include a step of heating the liquid film of the mixture.

With this method, the low surface tension liquid is supplied to the upper surface of the substrate held in a horizontal posture. Thereby, the processing liquid and the low surface tension liquid are mixed, and the liquid film of the mixture is formed on the front surface of the substrate. By then heating the liquid film of the mixture, the processing liquid having the low boiling point contained in the mixture can be evaporated. As a result, the processing liquid in the liquid film can be completely replaced with the low surface tension liquid.

The mixture heating step may heat the mixture at a predetermined high temperature which is higher than the boiling point of the processing liquid and lower than the boiling point of the low surface tension liquid.

With this method, by heating the mixture at the temperature which is higher than the boiling point of the processing liquid and lower than the boiling point of the low surface tension liquid, the low surface tension liquid in the mixture is hardly evaporated. Meanwhile, the evaporation of the processing liquid in the mixture is facilitated. That is, only the processing liquid in the mixture can be efficiently evaporated. Thereby, complete replacement with the low surface tension liquid can be realized in a shorter time. After the mixture heating step, a liquid film of the low surface tension liquid having a predetermined thickness can also be held on the upper surface of the substrate.

The above method may further include a substrate holding step of horizontally holding the substrate, the mixture forming step may include a step of forming a liquid film of the mixture covering an upper surface of the substrate, and the replacing step may include a liquid film removed region forming step of forming a liquid film removed region in the liquid film of the mixture, and a liquid film removed region expanding step of expanding the liquid film removed region toward an outer periphery of the substrate.

With this method, the liquid film of the mixture is formed on the upper surface of the substrate held in a horizontal posture. The liquid film removed region is formed in the liquid film of the mixture, and further, the liquid film removed region is expanded until it covers the entire substrate. On the upper surface of the substrate, while the mixture is evaporated at the gas-liquid-solid interface of the liquid film of the mixture, the liquid film removed region is expanded. At the gas-liquid-solid interface, the processing liquid having the low boiling point is mainly evaporated. As a result, concentration of the low surface tension liquid is increased. At this time, only the low surface tension liquid exists at the gas-liquid-solid interface, and in an around-interface portion of the liquid film of the mixture, such a concentration gradient that the concentration of the low surface tension liquid is lowered with distance from the gas-liquid-solid interface is formed. That is, at the gas-liquid-solid interface, the processing liquid can be completely replaced with the low surface tension liquid. It is considered that when a liquid is completely removed from between portions of a pattern, surface tension of the liquid acts on the pattern. By completely replacing with the low surface tension liquid at the gas-liquid-solid interface, the surface tension acting on the pattern at the time of completely removing the liquid from the pattern can be suppressed to be low. Thus, the collapse of the pattern can be suppressed.

The above method may further include a puddling step of bringing the substrate into a stationary state or rotating the substrate about the rotation axis at a puddle speed in parallel with the mixture liquid film forming step.

With this method, the puddling step is executed in parallel with the mixture liquid film forming step. Thus, the discharge of the low surface tension liquid from the substrate can be suppressed. Thereby, a use amount of the low surface tension liquid can be reduced.

In the above method, the liquid film removed region forming step may include a gas blowing step of blowing gas to the upper surface of the substrate.

With this method, by blowing the gas to the liquid film of the mixture, part of the mixture contained in the liquid film of the mixture is blown off and removed. Thereby, the liquid film removed region can be easily formed.

The liquid film removed region expanding step may include a high speed rotating step of rotating the substrate at higher speed than that of the time of the mixture liquid film forming step.

With this method, by strong centrifugal force which is generated by rotating the substrate at high speed, the liquid film removed region can be expanded.

The gas may include a high-temperature gas having a higher temperature than an ordinary temperature.

With this method, by supplying the high-temperature gas to the upper surface of the substrate, the evaporation of the processing liquid at the gas-liquid-solid interface of the liquid film of the mixture can be facilitated. Thereby, the concentration gradient of the low surface tension liquid in the around-interface portion of the liquid film of the mixture can be made radical. Therefore, only the low surface tension liquid can exist at the gas-liquid-solid interface.

The processing liquid may include water, and the low surface tension liquid may include EG.

With this method, the EG is supplied to the front surface of the substrate where the water remains. Thereby, the water and the EG are mixed, and the mixture is formed on the front surface of the substrate. Then, the water having the low boiling point contained in the mixture is mainly evaporated. As a result, the water on the front surface of the substrate can be completely replaced with the EG.

The mixture is formed by the supply of the EG and the water contained in the mixture is evaporated, so that only the EG remains. Thus, speed to replace the water with the EG can be increased. Thereby, the water on the front surface of the substrate can be completely replaced with the EG in a short time. Therefore, the front surface of the substrate can be dried in a short time while reducing the collapse of the pattern. Thereby, a drying time can be shortened and a use amount of an organic solvent can be reduced.

With this method, the EG is supplied to the front surface of the substrate where the water remains. Thereby, the water and the EG are mixed, and the mixture is formed on the front surface of the substrate. Then, the water having the low boiling point contained in the mixture is evaporated. As a result, the water on the front surface of the substrate can be completely replaced with the EG.

The mixture is formed by the supply of the EG and the water contained in the mixture is evaporated, so that only the EG remains. Thus, the speed to replace the water with the EG can be increased. Thereby, the water on the front surface of the substrate can be completely replaced with the EG in a short time. Therefore, the front surface of the substrate can be dried in a short time while reducing the collapse of the pattern.

A fourth aspect of the present invention is to provide a substrate processing apparatus including a substrate holding unit arranged to horizontally hold a substrate, a processing liquid supplying unit arranged to supply a processing liquid to an upper surface of the substrate, a low surface tension liquid supplying unit arranged to supply a low surface tension liquid having a higher boiling point than that of the processing liquid and a lower surface tension than that of the processing liquid to the upper surface of the substrate, and a controller that executes a mixture liquid film forming step of, by controlling the processing liquid supplying unit and the low surface tension liquid supplying unit to supply the low surface tension liquid to the upper surface of the substrate where the processing liquid remains, forming a liquid film of a mixture of the remaining processing liquid and the low surface tension liquid to cover the upper surface of the substrate, a replacing step of evaporating the processing liquid from the liquid film of the mixture formed on the upper surface of the substrate and replacing the mixture on an interface between the liquid film of the mixture and the upper surface of the substrate with the low surface tension liquid, and a drying step of removing the low surface tension liquid from the upper surface of the substrate and drying the upper surface of the substrate.

With this arrangement, the low surface tension liquid is supplied to the upper surface of the substrate where the processing liquid remains. Thereby, the processing liquid and the low surface tension liquid are mixed, and the liquid film of the mixture is formed on the front surface of the substrate. Then, the processing liquid having the low boiling point contained in the liquid film of the mixture is evaporated. As a result, the processing liquid on the front surface of the substrate can be completely replaced with the low surface tension liquid.

The mixture is formed by the supply of the low surface tension liquid and the processing liquid contained in the mixture is evaporated, so that only the low surface tension liquid remains. Thus, the speed to replace the processing liquid with the low surface tension liquid can be increased. Thereby, the processing liquid on the front surface of the substrate can be completely replaced with the low surface tension liquid in a short time. Therefore, the front surface of the substrate can be dried in a short time while reducing the collapse of the pattern.

In a preferred embodiment of the present invention, the above method further includes a heating unit arranged to heat the liquid film of the mixture which is formed on the upper surface, an object to be controlled by the controller includes the heating unit, and the controller executes the replacing step by controlling the heating unit to heat the liquid film of the mixture.

With this arrangement, the low surface tension liquid is supplied to the upper surface of the substrate held in a horizontal posture. Thereby, the processing liquid and the low surface tension liquid are mixed, and the liquid film of the mixture is formed on the front surface of the substrate. By then heating the liquid film of the mixture, the processing liquid having the low boiling point contained in the liquid film of the mixture can be evaporated. As a result, the processing liquid in the liquid film can be completely replaced with the low surface tension liquid.

The aforementioned as well as other objects, features, and effects of the present invention will be made clear by the following description of the preferred embodiments, with reference to the accompanying drawings.

### BRIEF DESCRIPTION OF THE DRAWINGS

FIG. 1 is an illustrative plan view for describing a layout of an interior of a substrate processing apparatus according to a first preferred embodiment of the present invention.

FIG. 2 is an illustrative sectional view for describing an arrangement example of a processing unit provided in the substrate processing apparatus.

FIG. 3 is a block diagram for describing an electrical arrangement of a main portion of the substrate processing apparatus.

FIG. 4 is a flowchart for describing an example of substrate processing performed by the substrate processing apparatus.

FIGS. 5A to 5C are illustrative sectional views for describing states of a mixture puddling step (S5 of FIG. 4) and a liquid film removed region forming step of a drying step (S6 of FIG. 4).

FIGS. 5D to 5F are illustrative sectional views for describing states of the liquid film removed region expanding step of the drying step (S6 of FIG. 4).

FIG. 6 is a sectional view showing an expanded state of a mixture liquid film in the liquid film removed region expanding step.

FIG. 7 is a view for describing a generation mechanism of Marangoni convection inside an inner peripheral portion of the mixture liquid film.

FIGS. 8A and 8B are plan views showing states of the inner peripheral portion of the mixture liquid film during expansion of a liquid film removed region.

FIG. 9 is a view showing a flow distribution model at a gas-liquid-solid interface in a water liquid film on an upper surface of a substrate, according to a reference mode.

FIG. 10 is a schematic sectional view showing movement of minute particles contained in an inner peripheral portion of the water liquid film, according to the reference mode.

FIG. 11 is a schematic plan view showing movement of the minute particles contained in the inner peripheral portion of the water liquid film, according to the reference mode.

FIGS. 12A and 12B are plan views showing states of the inner peripheral portion of the water liquid film during expansion of the liquid film removed region, according to the reference mode.

FIG. 13 is a schematic view for describing a general arrangement of a substrate processing apparatus according to a second preferred embodiment of the present invention.

FIG. 14 is a schematic view showing a state of pull-up and drying in the substrate processing apparatus according to the second preferred embodiment of the present invention.

FIG. 15 is an illustrative sectional view for describing an arrangement example of a processing unit provided in a substrate processing apparatus according to a third preferred embodiment of the present invention.

FIG. 16 is a block diagram for describing an electrical arrangement of a main portion of the substrate processing apparatus.

FIG. 17 is a flowchart for describing an example of substrate processing performed by the substrate processing apparatus.

FIGS. 18A to 18C are illustrative sectional views for describing states of a mixture forming step (S14 of FIG. 17), a mixture heating step (S15 of FIG. 17), and a drying step (S16 of FIG. 17).

FIGS. 19A to 19C are illustrative sectional views showing states of a front surface of a substrate in a rinsing step (S13 of FIG. 17) and the mixture forming step (S14 of FIG. 4).

FIGS. 19D to 19F are illustrative sectional views showing states of the front surface of the substrate in the mixture heating step (S15 of FIG. 17) and the drying step.

FIG. 20 is an illustrative sectional view for describing an arrangement example of a processing unit provided in a substrate processing apparatus according to a fourth preferred embodiment of the present invention.

FIG. 21 is a block diagram for describing an electrical arrangement of a main portion of the substrate processing apparatus.

FIG. 22 is a flowchart for describing an example of substrate processing performed by the substrate processing apparatus.

FIGS. 23A to 23C are illustrative sectional views for describing states of a mixture forming step (S24 of FIG. 22) and a liquid film removed region forming step (S25 of FIG. 22).

FIGS. 23D to 23F are illustrative sectional views for describing states of a liquid film removed region expanding step (S26 of FIG. 22).

FIG. 24 is an expanded sectional view for describing an inner peripheral portion of a water/EG mixture liquid film.

FIG. 25 is a schematic view for describing a general arrangement of a substrate processing apparatus according to a fifth preferred embodiment of the present invention.

FIG. 26 is an illustrative sectional view for describing the principle of pattern collapse due to surface tension.

### DESCRIPTION OF EMBODIMENTS

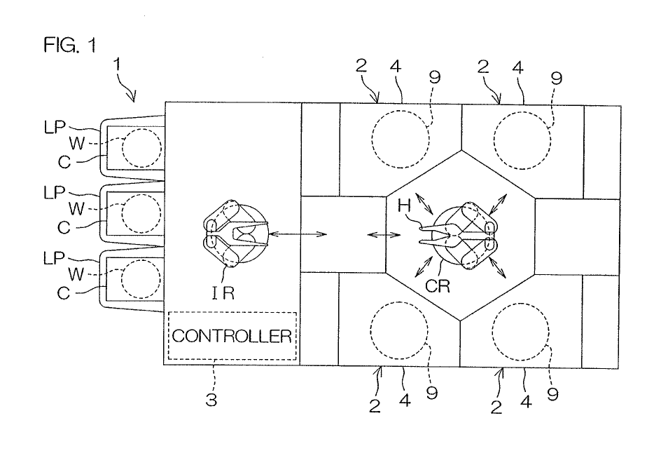

FIG. 1 is an illustrative plan view for describing a layout of an interior of a substrate processing apparatus according to a first preferred embodiment of the present invention. The substrate processing apparatus 1 is a single substrate processing type apparatus that processes substrates W such as silicon wafers one at a time. In the preferred embodiment, the substrates Ware disk-shaped substrates. The substrate processing apparatus 1 includes plural processing units 2 that process the substrates W with a processing liquid, load ports LP in each of which is mounted a carrier C that houses plural substrates W to be processed by the processing units 2, transfer robots IR and CR that transport the substrates W between the load ports LP and the processing units 2, and a controller 3 that controls the substrate processing apparatus 1. The transfer robot IR transports the substrates W between the carriers C and the transfer robot CR. The transfer robot CR transports the substrates W between the transfer robot IR and the processing units 2. The plural processing units 2 have, for example, the same arrangement.

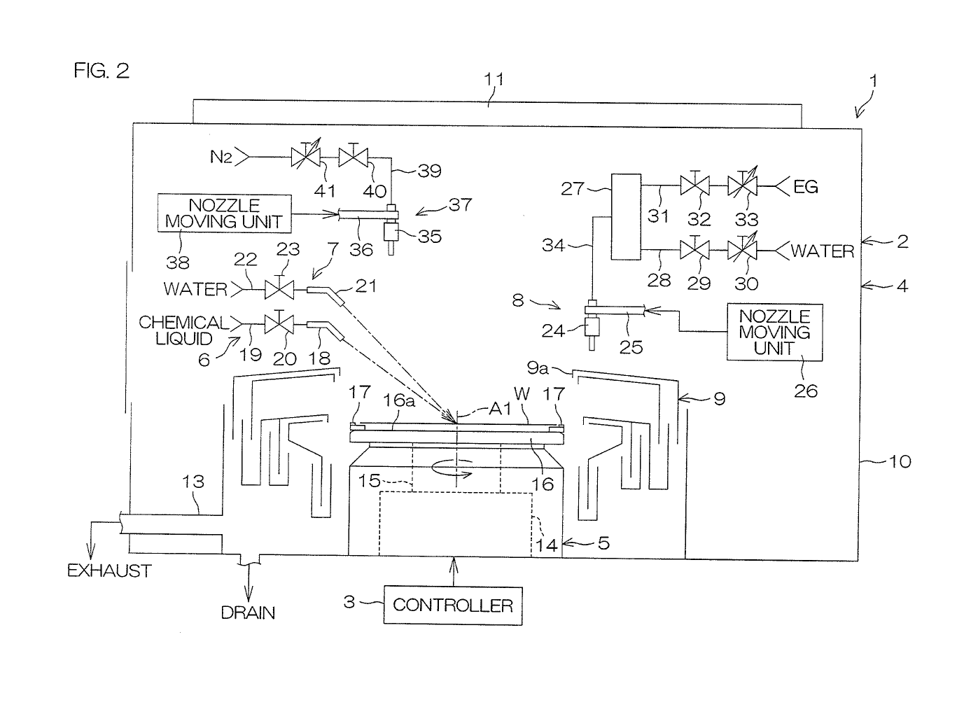

FIG. 2 is an illustrative sectional view for describing an arrangement example of the processing unit 2.

The processing unit 2 includes a box-shaped processing chamber 4, a spin chuck 5 that holds a single substrate W in a horizontal posture inside the processing chamber 4 and rotates the substrate W about the vertical rotational axis A1 passing through a center of the substrate W, a chemical liquid supplying unit 6 arranged to supply a chemical liquid (processing liquid) to an upper surface of the substrate W which is held by the spin chuck 5, a water supplying unit 7 arranged to supply water (processing liquid) to the upper surface of the substrate W which is held by the spin chuck 5, a mixture supplying unit 8 that supplies a mixture of water (first liquid) and ethylene glycol (second liquid: hereinafter, referred to as “EG”) (hereinafter, the mixture will be referred to as “water/EG mixture”) to the upper surface (front surface) of the substrate W, and a cylindrical processing cup 9 surrounding the spin chuck 5.

The processing chamber 4 includes a box-shaped partition wall 10, an FFU (fan filter unit) 11 serving as a blower unit that feeds clean air from an upper portion of the partition wall 10 to the inside of the partition wall 10 (corresponding to an interior of the processing chamber 4), and an exhaust apparatus (not shown) that exhausts gas in the processing chamber 4 from a lower portion of the partition wall 10.

The FFU 11 is disposed above the partition wall 10 and attached to a ceiling of the partition wall 10. The FFU 11 feeds clean air to the interior of the processing chamber 4 from the ceiling of the partition wall 10. The exhaust apparatus is connected to a bottom portion of the processing cup 9 via an exhaust duct 13 connected to an interior of the processing cup 9, and suctions the interior of the processing cup 9 from the bottom portion of the processing cup 9. A down flow (downward flow) is formed in the processing chamber 4 by the FFU 11 and the exhaust apparatus.

As the spin chuck 5, a clamping type chuck that clamps the substrate Win the horizontal direction to hold the substrate W horizontally is adopted. Specifically, the spin chuck 5 includes a spin motor 14, a spin shaft 15 integrated with a drive shaft of the spin motor 14, and a disk-shaped spin base 16 substantially horizontally attached to an upper end of the spin shaft 15.

The spin base 16 includes a horizontal and circular upper surface 16a having an outer diameter which is larger than an outer diameter of the substrate W. Plural (not less than three; for example, six) clamping members 17 are disposed in a peripheral edge portion of the upper surface 16a. In the upper surface peripheral edge portion of the spin base 16, the plural clamping members 17 are disposed at suitable intervals, for example, at equal intervals on a circumference corresponding to an outer peripheral shape of the substrate W.

The chemical liquid supplying unit 6 includes a chemical liquid nozzle 18. The chemical liquid nozzle 18 is, for example, a straight nozzle that discharges a liquid in a state of a continuous stream and is disposed fixedly above the spin chuck 5 with its discharge port directed at a central portion of the upper surface of the substrate W. A chemical liquid piping 19 to which chemical liquid from a chemical liquid supply source is supplied is connected to the chemical liquid nozzle 18. A chemical liquid valve 20 arranged to switch between supply/stop of supply of the chemical liquid from the chemical liquid nozzle 18 is interposed in an intermediate portion of the chemical liquid piping 19. When the chemical liquid valve 20 is opened, the chemical liquid of continuous stream supplied from the chemical liquid piping 19 to the chemical liquid nozzle 18 is discharged from the discharge port set in a lower end of the chemical liquid nozzle 18. When the chemical liquid valve 20 is closed, the supply of the chemical liquid from the chemical liquid piping 19 to the chemical liquid nozzle 18 is stopped.

Specific examples of the chemical liquid are an etching liquid and a cleaning liquid. More specifically, the chemical liquid may be hydrofluoric acid, SC1 (ammonia/hydrogen peroxide mixture), SC2 (hydrochloric acid/hydrogen peroxide mixture), ammonium fluoride, buffered hydrogen fluoride (mixture of hydrofluoric acid and ammonium fluoride), etc.

The water supplying unit 7 includes a first water nozzle 21. The first water nozzle 21 is, for example, a straight nozzle that discharges a liquid in a state of a continuous stream and is disposed fixedly above the spin chuck 5 with its discharge port directed at the central portion of the upper surface of the substrate W. A first water piping 22 to which water from a water supply source is supplied is connected to the first water nozzle 21. A first water valve 23 arranged to switch between supply/stop of supply of water from the first water nozzle 21 is interposed in an intermediate portion of the first water piping 22. When the first water valve 23 is opened, the water of continuous stream supplied from the first water piping 22 to the first water nozzle 21 is discharged from the discharge port set in a lower end of the first water nozzle 21. When the first water valve 23 is closed, the supply of the water from the first water piping 22 to the first water nozzle 21 is stopped. The water is, for example, deionized water (DIW). However, the water of the present invention is not limited to DIW but may be any of carbonated water, electrolyzed ion water, hydrogen water, ozone water, and aqueous hydrochloric acid solution of dilute concentration (for example, of about 10 ppm to 100 ppm).

Each of the chemical liquid nozzle 18 and the first water nozzle 21 does not need to be disposed fixedly with respect to the spin chuck 5. For example, a so-called scanning nozzle mode in which the nozzle is attached to an arm swingable in a horizontal plane above the spin chuck 5 and a liquid landing position of the processing liquid (the chemical liquid or the water) on the upper surface of the substrate W is scanned by swinging of the arm may be adopted.

The mixture supplying unit 8 includes a mixture nozzle 24 arranged to discharge the water/EG mixture, a first nozzle arm 25 in which the mixture nozzle 24 is attached to a tip portion, and a first nozzle moving unit 26 that moves the mixture nozzle 24 by moving the first nozzle arm 25. The mixture nozzle 24 is, for example, a straight nozzle that discharges the water/EG mixture in a state of a continuous stream and is attached to the horizontally extending first nozzle arm 25 with its discharge port directed downward for example.

The mixture supplying unit 8 also includes a mixing portion 27 arranged to mix the water and the EG, a second water piping 28 connected to the mixing portion 27 to supply the water from the water supply source to the mixing portion 27, a second water valve 29 and a first flow rate regulation valve 30 both of which are interposed in the second water piping 28, an EG piping 31 connected to the mixing portion 27 to supply the EG from an EG supply source to the mixing portion 27, an EG valve 32 and a second flow rate regulation valve 33 both of which are interposed in the EG piping 31, and a mixture piping 34 that supplies the water/EG mixture from the mixing portion 27 to the mixture nozzle 24. Like the water supplying unit 7, the water is, for example, deionized water (DIW). However, the water of the present invention is not limited to DIW but may be any of carbonated water, electrolyzed ion water, hydrogen water, ozone water, and aqueous hydrochloric acid solution of dilute concentration (for example, of about 10 ppm to 100 ppm). The boiling point of the water (DIW) is 100° C. and surface tension is 72.75 at an ordinary temperature. The boiling point of the EG is 197.5° C. and surface tension is 47.3 at an ordinary temperature. That is, the EG is a liquid having the higher boiling point than that of the water and lower surface tension than that of the water.

The second water valve 29 opens and closes the second water piping 28. The first flow rate regulation valve 30 adjusts an opening degree of the second water piping 28 to regulate a flow rate of the water supplied to the mixing portion 27. The EG valve 32 opens and closes the EG piping 31. The second flow rate regulation valve 33 adjusts an opening degree of the EG piping 31 to regulate a flow rate of the water supplied to the mixing portion 27. Each of the first and second flow rate regulation valves 30, 33 includes a valve body (not shown) inside which a valve seat is provided, a valve element that opens and closes the valve seat, and an actuator (not shown) that moves the valve element between an open position and a close position. The same applies to the other flow rate regulation valves.

When the second water valve 29 and the EG valve 32 are opened, the water from the second water piping 28 and the EG from the EG piping 31 are supplied to the mixing portion 27, and the water and the EG are sufficiently mixed (agitated) in the mixing portion 27, so that the water/EG mixture is produced. The water/EG mixture produced in the mixing portion 27 is supplied to the mixture nozzle 24 and discharged, for example, downward from the discharge port of the mixture nozzle 24. A mixing ratio between the water and the EG in the water/EG mixture is regulated by opening degree regulation by the first and second flow rate regulation valves 30, 33.

As shown in FIG. 2, the processing cup 9 is disposed further outward of the substrate W held by the spin chuck 5 (in the direction of separating from the rotation axis A1). The processing cup 9 surrounds the spin base 16. When the processing liquid is supplied to the substrate W in a state where the spin chuck 5 rotates the substrate W, the processing liquid supplied to the substrate W is spun off to a periphery of the substrate W. When the processing liquid is supplied to the substrate W, an upper end portion 9a of the upward-opening processing cup 9 is disposed higher than the spin base 16. Therefore, the processing liquid discharged to the periphery of the substrate W such as the chemical liquid and the water is received by the processing cup 9. The processing liquid received by the processing cup 9 is fed to a recovery apparatus or a draining apparatus (not shown).

The processing unit 2 further includes a gas unit 37 arranged to supply gas to the upper surface of the substrate W held by the spin chuck 5.

The gas unit 37 includes a gas nozzle 35 that discharges nitrogen gas serving as an example of inert gas toward the upper surface of the substrate W, a second nozzle arm 36 in which the gas nozzle 35 is attached to a tip portion, and a second nozzle moving unit 38 that moves the gas nozzle 35 by moving the second nozzle arm 36. The gas nozzle 35 is attached to the horizontally extending second nozzle arm 36 with its discharge port directed downward for example.

A gas piping 39 to which a high-temperature inert gas (higher than an ordinary temperature, for example, of 30 to 300° C.) from an inert gas supply source is supplied is connected to the gas nozzle 35. A gas valve 40 arranged to switch between supply/stop of supply of the inert gas from the gas nozzle 35 and a third flow rate regulation valve 41 arranged to adjust an opening degree of the gas piping 39 to regulate a flow rate of the inert gas discharged from the gas nozzle 35 are interposed in an intermediate portion of the gas piping 39. When the gas valve 40 is opened, the inert gas supplied from the gas piping 39 to the gas nozzle 35 is discharged from the discharge port. When the gas valve 40 is closed, the supply of the inert gas from the gas piping 39 to the gas nozzle 35 is stopped. The inert gas is not limited to nitrogen gas but may be CDA (clean dry air).

FIG. 3 is a block diagram for describing an electrical arrangement of a main portion of the substrate processing apparatus 1.

The controller 3 is arranged using, for example, a microcomputer. The controller 3 has a computing unit, such as CPU, etc., a storage unit, such as a fixed memory device, a hard disk drive, etc., and an input/output unit. A program executed by the computing unit is stored in the storage unit.

The controller 3 controls operations of the spin motor 14, the first and second nozzle moving units 26, 38, etc., in accordance with the predetermined program. Further, the controller 3 controls opening and closing operations, etc., of the chemical liquid valve 20, the first and second water valves 23, 29, the EG valve 32, the gas valve 40, the first, second, and third flow rate regulation valves 30, 33, 41, etc.

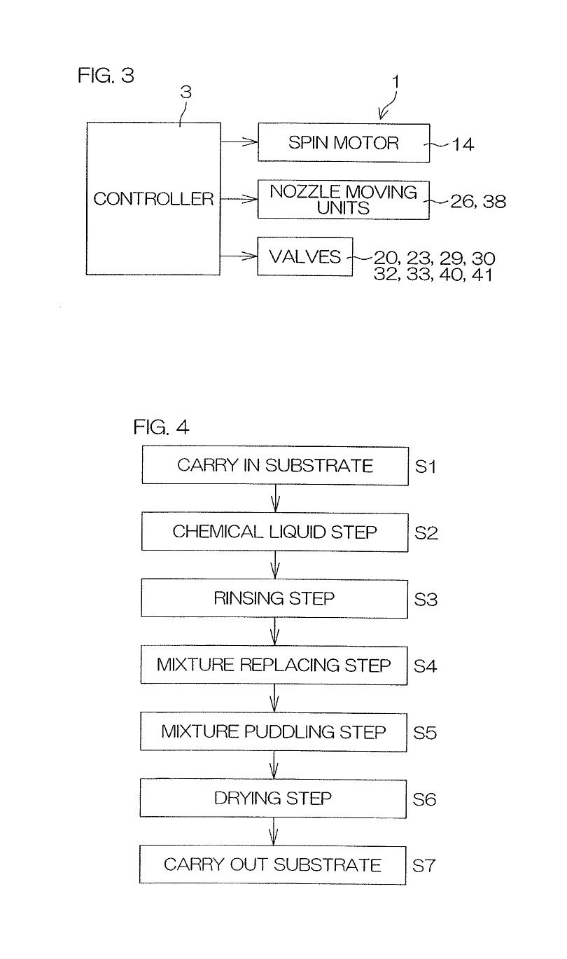

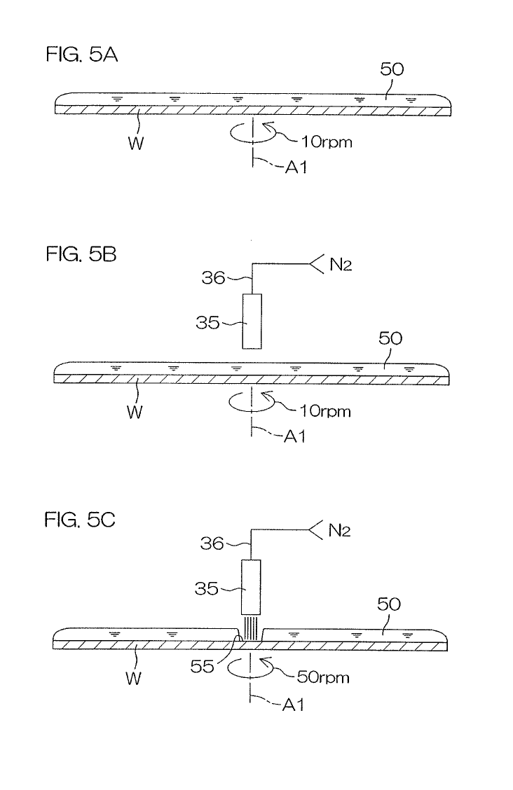

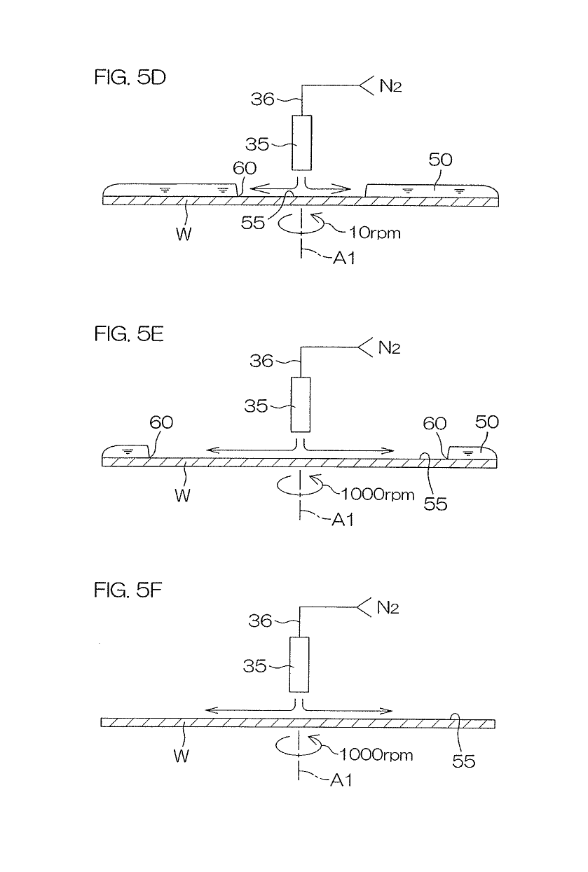

FIG. 4 is a flowchart for describing an example of substrate processing performed by the substrate processing apparatus 1. FIGS. 5A to 5F are illustrative views for describing a mixture puddling step, a liquid film removed region forming step, and a liquid film removed region expanding step. With reference to FIGS. 1 to 5F, the substrate processing will be described.

The unprocessed substrate W is carried into the processing unit 2 from the carrier C by the transfer robots IR, CR and carried into the interior of the processing chamber 4, the substrate W is delivered to the spin chuck 5 in a state where the front surface (the surface to be processed: the pattern forming surface in the present preferred embodiment) of the substrate is directed upward, and the substrate W is held by the spin chuck 5 (S1: substrate carry-in step (substrate holding step)). Before carrying in the substrate W, the mixture nozzle 24 and the gas nozzle 35 are retracted to home positions set on the side of the spin chuck 5.

After the transfer robot CR is retracted out of the processing unit 2, the controller 3 executes a chemical liquid step (Step S2). Specifically, the controller 3 drives the spin motor 14 to rotate the spin base 16 at a predetermined liquid processing rotation speed (for example, about 800 rpm). The controller 3 opens the chemical liquid valve 20. Thereby, the chemical liquid is supplied from the chemical liquid nozzle 18 toward the upper surface of the rotating substrate W. The supplied chemical liquid is spread over the entire surface of the substrate W by centrifugal force, and chemical liquid processing using the chemical liquid is performed for the substrate W. When a predetermined time period elapses after the start of the discharge of the chemical liquid, the controller 3 closes the chemical liquid valve 20 to stop the discharge of the chemical liquid from the chemical liquid nozzle 18.

Next, the controller 3 executes a water rinsing step (Step S3). The water rinsing step (S3) is a step of replacing the chemical liquid on the substrate W with the water to remove the chemical liquid from the top of the substrate W. Specifically, the controller 3 opens the first water valve 23. Thereby, the water is supplied from the first water nozzle 21 toward the upper surface of the rotating substrate W. The supplied water is spread over the entire surface of the substrate W by the centrifugal force. By the water, the chemical liquid attached to the top of the substrate W is washed away.

Next, the controller 3 executes a water/EG mixture replacing step (Step S4). The water/EG mixture replacing step (S4) is a step of replacing the water on the substrate W with the water/EG mixture. The controller 3 controls the first nozzle moving unit 26 to move the mixture nozzle 24 from the home position on the side of the spin chuck 5 to a position above the central portion of the upper surface of the substrate W. The controller 3 opens the second water valve 29 and the EG valve 32 to supply the water/EG mixture to the central portion of the upper surface (front surface) of the substrate W. The supplied water/EG mixture is spread over the entire surface of the substrate W by the centrifugal force and replaced with the water on the substrate W (mixture replacing step). EG concentration in the water/EG mixture supplied at this time is set to be a predetermined concentration within a range of, for example, 1 weight % or more and less than 20 weight %.

When a predetermined time period elapses after the start of the supply of the water/EG mixture, in a state where the entire upper surface of the substrate W is covered with the water/EG mixture, the controller 3 controls the spin motor 14 to stepwise reduce the rotational speed of the substrate W from the liquid processing speed to puddle speed (zero or a low rotational speed of about 40 rpm or less, for example, about 10 rpm). After that, the rotational speed of the substrate W is maintained at the puddle speed. Thereby, as shown in FIG. 5A, a water/EG mixture liquid film (hereinafter, the mixture liquid film) 50 covering the entire upper surface of the substrate W is supported in a puddle shape on the upper surface of the substrate W (S5: mixture puddling step (liquid film forming step, puddling step)). In this state, the centrifugal force acting on the mixture liquid film 50 on the upper surface of the substrate W is smaller than the surface tension acting between the water/EG mixture and the upper surface of the substrate W, or the above-described centrifugal force is substantially balanced with the above-described surface tension. By the speed reduction of the substrate W, the centrifugal force acting on the water/EG mixture on the substrate W is weakened, and an amount of the water/EG mixture discharged from the top of the substrate W is reduced. The rinsing step is executed following the chemical liquid step of removing particles from the upper surface of the substrate W with the chemical liquid. Thus, the particles are sometimes contained in the mixture liquid film 50. In the mixture puddling step (S5), the supply of the water/EG mixture to the substrate W may be continued even after the puddle-shaped mixture liquid film 50.

Before the end of the mixture puddling step (S5), the controller 3 retracts the mixture nozzle 24 to the home position and controls the second nozzle moving unit 38 to dispose the gas nozzle 35 above the substrate W from the home position on the side of the spin chuck 5 as shown in FIG. 5B.

When a predetermined time period elapses after the speed reduction of the substrate W to the puddle speed, the controller 3 executes a drying step (Step S6). In the drying step (S6), the liquid film removed region forming step and the liquid film removed region expanding step are executed in this order. The liquid film removed region forming step is a step of forming a liquid film removed region 55 from which the mixture is removed in a central portion of the mixture liquid film 50. The liquid film removed region expanding step is a step of expanding the liquid film removed region 55 over the entire upper surface of the substrate W.

In the liquid film removed region forming step, the controller 3 opens the gas valve 40 to discharge the inert gas from the gas nozzle 35 toward the central portion of the upper surface of the substrate W (gas blowing step), and controls the spin motor 14 to accelerate the substrate W to a predetermined hole making speed (for example, about 50 rpm) (high speed rotating step). By blowing the inert gas to the central portion of the mixture liquid film 50 on the upper surface of the substrate W, the water/EG mixture in the central portion of the mixture liquid film 50 is blown away and removed from the central portion of the upper surface of the substrate W by blowing pressure (gas pressure). By the rotational speed of the substrate W reaching the above-described hole making speed (for example, about 50 rpm), a relatively strong centrifugal force acts on the mixture liquid film 50 on the substrate W. Thereby, as shown in FIG. 5C, the circular liquid film removed region 55 is formed in the central portion of the upper surface of the substrate W. Although the hole making speed is set to be about 50 rpm, the hole making speed may be any rotational speed which is equal to or higher than the above-described speed. Next to the liquid film removed region forming step, the liquid film removed region expanding step is executed.

In the liquid film removed region expanding step, the controller 3 controls the spin motor 14 to increase the rotational speed of the substrate W to a predetermined first drying speed (for example, 1,000 rpm). In accordance with the increase in the rotational speed of the substrate W, the liquid film removed region 55 is expanded as shown in FIGS. 5D, 5E. By the expansion of the liquid film removed region 55, a gas-liquid-solid interface 60 of the mixture liquid film 50 between the liquid film removed region 55 and the upper surface of the substrate W is moved radially outward of the substrate W. As shown in FIG. 5F, by then expanding the liquid film removed region 55 over the entire substrate W, all the mixture liquid film 50 is discharged out of the substrate W.

After the liquid film removed region 55 is expanded over the entire upper surface of the substrate W, the liquid film removed region expanding step is ended. In accordance with the end of the liquid film removed region expanding step, the controller 3 closes the gas valve 40 to stop the discharge of the inert gas from the gas nozzle 35.

After that, the controller 3 increases the rotational speed of the substrate W to about 1,500 rpm. Thereby, the upper surface of the substrate W is further dried.

When a predetermined time period elapses after the start of the spin drying step (S6), the controller 3 controls the spin motor 14 to stop the rotation of the spin chuck 5. After that, the transfer robot CR enters the processing unit 2 and carries the processed substrate W out of the processing unit 2 (Step S7). The substrate W is delivered from the transfer robot CR to the transfer robot IR, and housed in the carrier C by the transfer robot IR.

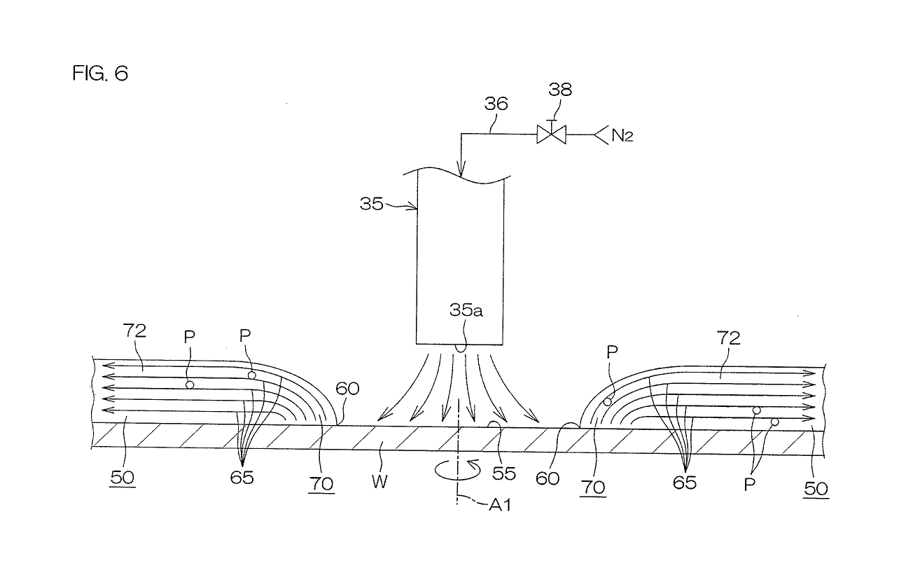

FIG. 6 is a sectional view showing an expanded state of the mixture liquid film 50 in the liquid film removed region expanding step.

The inert gas is discharged downward from the gas nozzle 35. When the substrate W is processed by the substrate processing apparatus 1, the discharge port 35a of the gas nozzle 35 is disposed at a lower position to face the upper surface of the substrate W with a predetermined gap. When the gas valve 40 is opened in this state, the inert gas discharged from the discharge port 35a is blown to the upper surface of the substrate W. Thereby, the water in the central portion of the mixture liquid film 50 is physically forced out by the blowing pressure (gas pressure), and the water is blown away and removed from the central portion of the upper surface of the substrate W. As a result, the liquid film removed region 55 is formed in the central portion of the upper surface of the substrate W.

After the formation of the liquid film removed region 55, an EG concentration gradient is formed inside an inner peripheral portion (around-interface portion) 70 of the mixture liquid film due to evaporation of the water at the gas-liquid-solid interface 60. Thereby, Marangoni convection 65 flowing from the gas-liquid-solid interface 60 to the side of a bulk (liquid bulk) 72 is generated.

After the formation of the liquid film removed region 55, the inert gas discharged from the discharge port 35a flows in the horizontal direction in a radial manner along the upper surface of the substrate W.

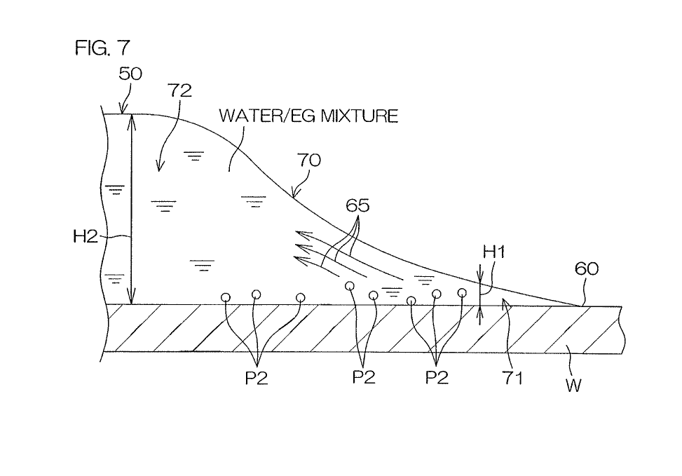

FIG. 7 is a view for describing a generation mechanism of the Marangoni convection 65 inside the inner peripheral portion 70 of the mixture liquid film.

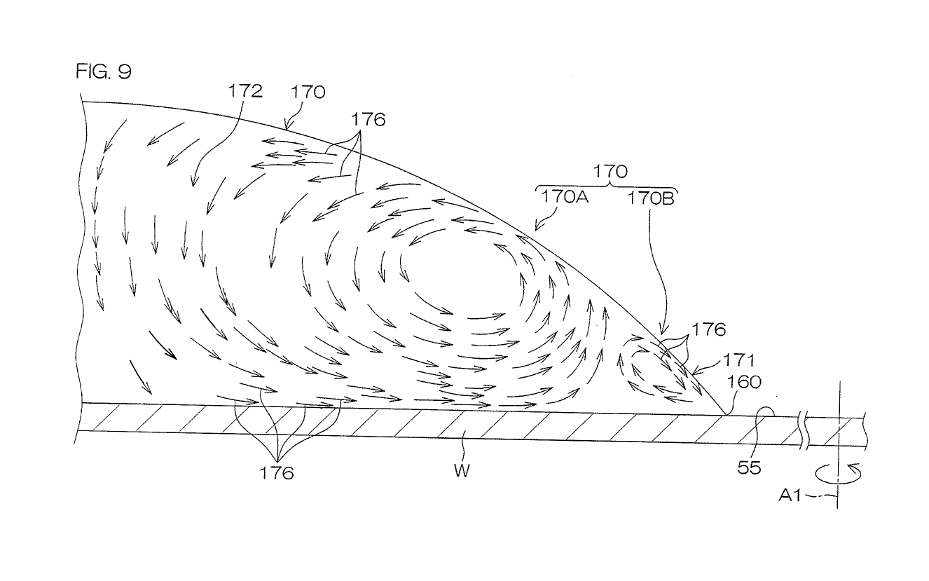

In a state where the substrate W is rotated and the liquid film removed region 55 (see FIG. 6) is formed in the mixture liquid film 50, the mixture is evaporated at the gas-liquid-solid interface 60 of the mixture liquid film 50. In the liquid film removed region forming step, while the mixture is evaporated at the gas-liquid-solid interface 60 of the mixture liquid film 50, the liquid film removed region 55 is expanded. At the gas-liquid-solid interface 60, the water having a relatively low boiling point is mainly evaporated. As a result, concentration of the EG having a relatively high boiling point and low surface tension is increased. Therefore, in the inner peripheral portion 70 of the mixture liquid film, such a concentration gradient that the EG concentration is increased toward the gas-liquid-solid interface 60 is formed. As a result, the Marangoni convection 65 flowing from an interface vicinity region 71 toward the bulk 72 is generated. The Marangoni convection 65 not only cancels heat convection 176 (see FIG. 9) generated in a second portion 70B (see FIG. 9) to be described later but also creates a new flow running from the interface vicinity region 71 toward the bulk 72 in the second portion 70B (see FIG. 9). The Marangoni convection 65 continues to be generated until the liquid film removed region 55 covers the entire substrate W after the formation of the liquid film removed region 55.

Therefore, in a case where minute particles P2 are contained in the inner peripheral portion 70 of the mixture liquid film (specifically, the second portion 70B shown in FIG. 9), as shown in FIG. 7, strong force acts on the minute particles P2 in the direction of receiving the Marangoni convection 65 and moving from the interface vicinity region 71 toward the bulk 72, that is, in the direction of separating from the gas-liquid-solid interface 60. Thereby, the minute particles P2 contained in the interface vicinity region 71 are moved radially outward (in the direction of separating from the gas-liquid-solid interface 60).

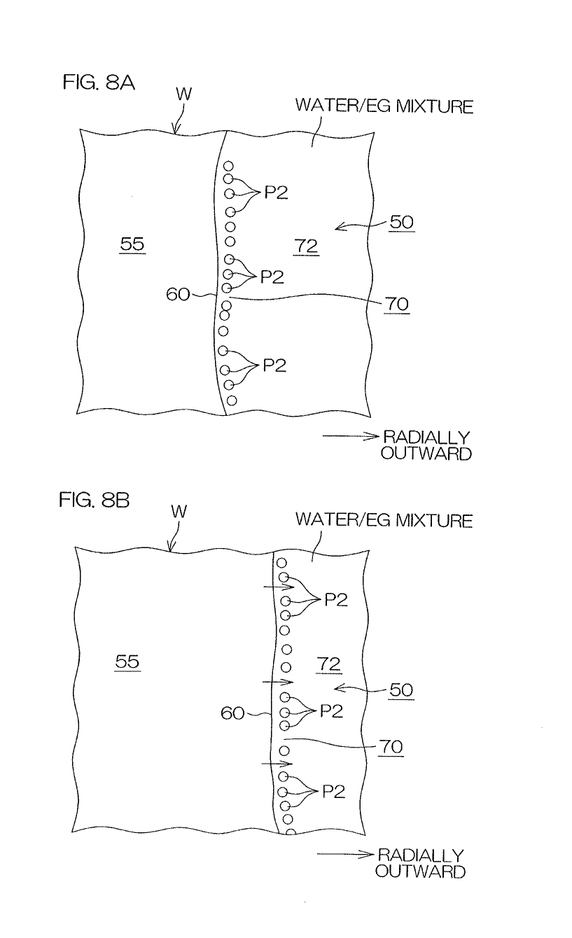

FIGS. 8A, 8B show states of the inner peripheral portion 70 of the mixture liquid film during expansion of the liquid film removed region 55. FIG. 8A shows a state where the minute particles P2 are contained in the inner peripheral portion 70 of the mixture liquid film (specifically, the second portion 170B shown in FIG. 9). The minute particles P2 are disposed side by side along the line of the gas-liquid-solid interface 60.

In this case, the minute particles P2 contained in the inner peripheral portion 70 of the mixture liquid film (second portion 70B) receive the Marangoni convection 65 (see FIG. 6) flowing in the direction of separating from the gas-liquid-solid interface 60 and move radially outward (in the direction of separating from the gas-liquid-solid interface 60). As a result, the minute particles are taken into the bulk 72 of the mixture liquid film 50. In accordance with the expansion of the liquid film removed region 55, the gas-liquid-solid interface 60 is moved radially outward of the substrate W (in the direction of moving toward the bulk 72). However, while the minute particles P2 are taken into the bulk 72, the liquid film removed region 55 is expanded. That is, when the gas-liquid-solid interface 60 is moved radially outward of the substrate W in accordance with the expansion of the liquid film removed region 55, the minute particles P2 are also moved radially outward together as shown in FIG. 8B.

By expanding the liquid film removed region 55 over the entire substrate W and completely discharging the mixture liquid film 50 from the upper surface of the substrate W (state shown in FIG. 5F), the entire upper surface of the substrate W is dried. The minute particles P2 contained in the bulk 72 of the mixture liquid film 50 are removed from the upper surface of the substrate W together with the mixture liquid film 50 without appearing at the liquid film removed region 55.

As described above, according to the present embodiment, the mixture liquid film 50 is formed on the upper surface of the substrate W held in a horizontal posture. The liquid film removed region 55 is formed in the mixture liquid film 50, and further, the liquid film removed region 55 is expanded until it covers the entire substrate W.

On the upper surface of the substrate W, while the mixture is evaporated at the gas-liquid-solid interface 60 of the mixture liquid film 50, the liquid film removed region 55 is expanded. At the gas-liquid-solid interface 60, the water having a relatively low boiling point is mainly evaporated. As a result, the concentration of the EG having a relatively high boiling point is increased. Therefore, in the inner peripheral portion 170 of the mixture liquid film, such a concentration gradient that the EG concentration is increased toward the gas-liquid-solid interface 60 is formed. Due to a concentration difference in the EG, inside the inner peripheral portion 170 of the mixture liquid film, the Marangoni convection 65 flowing in the direction of separating from the gas-liquid-solid interface 60 is generated. After the formation of the liquid film removed region 55, the Marangoni convection 65 continues to be generated until the liquid film removed region 55 covers the entire substrate W.

Thereby, the minute particles P2 contained in the inner peripheral portion 70 of the mixture liquid film receive the Marangoni convection 65 and move in the direction of separating from the gas-liquid-solid interface 60. Therefore, the minute particles P2 are taken into the mixture liquid film 50. In accordance with the expansion of the liquid film removed region 55, the gas-liquid-solid interface 60 is moved radially outward of the substrate W. However, while the minute particles P2 are taken into the bulk 72 of the mixture liquid film 50, the liquid film removed region 55 is expanded. The minute particles P2 are then discharged from the upper surface of the substrate W together with the mixture liquid film 50 without appearing at the liquid film removed region 55. Thereby, after drying the substrate W, the minute particles P2 do not remain on the upper surface of the substrate W. Therefore, the entire upper surface of the substrate W can be dried while reducing or preventing generation of the minute particles P2.

At the gas-liquid-solid interface 60 of the mixture liquid film 50, the concentration of the EG having lower surface tension than that of the water can be increased. Therefore, pattern collapse of the front surface of the substrate W at the time of drying can be suppressed.

In the mixture puddling step, no great centrifugal force acts on the substrate W. Thus, thickness of the mixture liquid film 50 formed on the upper surface of the substrate W can be maintained thick. Since the thickness of the inner peripheral portion 70 of the mixture liquid film 50 is large, the Marangoni convection 65 can be stably generated in the inner peripheral portion 70.

By supplying the high-temperature inert gas to the upper surface of the substrate W, the evaporation of the water at the gas-liquid-solid interface 60 of the mixture liquid film 50 can be facilitated. Thereby, the EG concentration gradient in the inner peripheral portion 70 of the mixture liquid film can be made radical. Therefore, the Marangoni convection 65 generated in the inner peripheral portion 70 of the mixture liquid film can be further strengthened.

At the time of the liquid film removed region expanding step, the substrate W is rotated at high speed. Thus, strong centrifugal force acts on the substrate W, and by the centrifugal force, a difference in the thickness in the inner peripheral portion 170 of the mixture liquid film can be made further remarkable. Thereby, the EG concentration gradient generated in the inner peripheral portion 170 of the mixture liquid film can be maintained large. Therefore, the Marangoni convection 65 generated in the inner peripheral portion 170 of the mixture liquid film can be further strengthened.

Next, a mechanism of generating the particles in accordance with the drying step will be described.

FIG. 9 is a view showing a flow distribution model at the gas-liquid-solid interface in a water liquid film 150 on the upper surface of the substrate W, according to a reference mode.

In the reference mode, unlike the processing example according to the above preferred embodiment, the puddle-shaped water liquid film 150 is formed. In that state, like the processing example according to the above preferred embodiment, the liquid film removed region forming step and the liquid film removed region expanding step are executed.

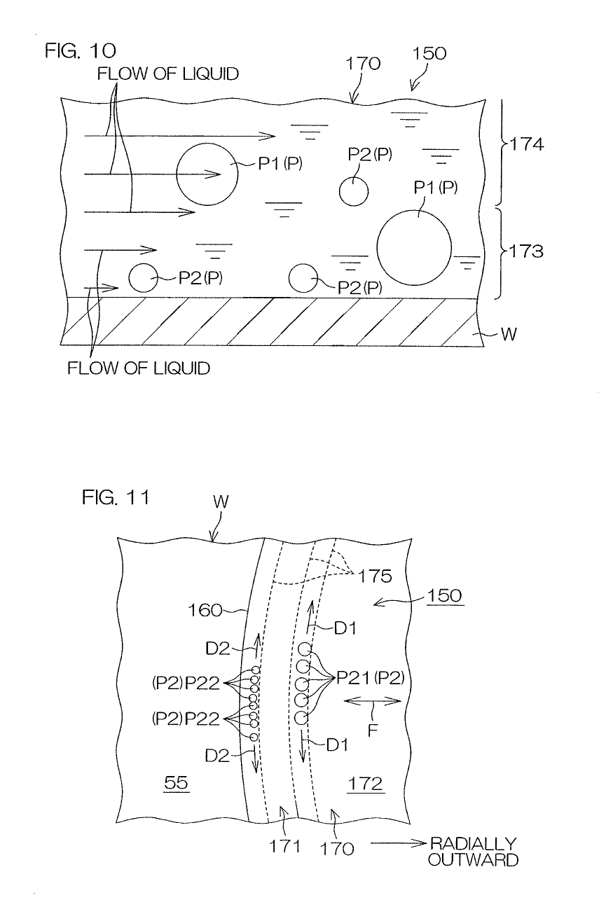

In this case, as shown in FIG. 9, in the liquid film removed region expanding step, the heat convection 176 is generated inside an inner peripheral portion 170 of the water liquid film. The heat convection 176 in the inner peripheral portion 170 of the water liquid film flows in the direction of separating from the side of a gas-liquid-solid interface 60 in a first region 170A placed on the side of a bulk 172. However, as shown in FIG. 9, in the second portion 170B on the side of the gas-liquid-solid interface 160 including an interface vicinity region 171, the heat convection 176 flows from the side of the bulk 172 to the side of the gas-liquid-solid interface 160. Therefore, in a case where the minute particles P2 are contained in the second portion 170B of the inner peripheral portion 170 (see FIGS. 10 to 12A, etc.), the minute particles P2 are pulled to the side of the gas-liquid-solid interface 160 and clumped together in the interface vicinity region 171. It is considered that such clumping of the minute particles P2 is due to not only the above-described heat convection 176 but also the van der Waals' force or the Coulomb's force between the adjacent minute particles P2.

FIG. 10 is a schematic sectional view showing movement of the minute particles P2 contained in the inner peripheral portion 170 of the water liquid film, according to the reference mode. FIG. 11 is a schematic plan view showing movement of the minute particles P2 contained in the inner peripheral portion 170 of the water liquid film, according to the reference mode.

As shown in FIG. 10, the inner peripheral portion 170 of the water liquid film includes a boundary layer 173 formed in the vicinity of the boundary with the upper surface of the substrate W, and a flowing layer 174 formed on the opposite side of the upper surface of the substrate W with respect to the boundary layer 173. In a case where the minute particles P2 are contained in the inner peripheral portion 170 of the water liquid film, in the flowing layer 174, particles P are strongly influenced by a flow irrespective of the size of grain diameters. Therefore, the particles P in the flowing layer 174 can be moved along the direction running along the flow.

Meanwhile, in the boundary layer 173, large particles P1 are influenced by the flow but minute particles P2 are hardly influenced by the flow. That is, although the large particles P1 in the boundary layer 173 can be moved along the direction running along the flow in the boundary layer 173, the minute particles P2 are not moved in the direction F running along the flow (see FIG. 11) in the boundary layer 173. However, the minute particles P2 are not attached to the upper surface of the substrate W but provided with a minute gap from the upper surface of the substrate W.

In the interface vicinity region 171 shown in FIG. 9, most parts of the inner peripheral portion 170 of the water liquid film are the boundary layer 173 shown in FIG. 10. In FIG. 9, a ratio of the flowing layer 174 (see FIG. 10) is increased toward the side of the bulk 72 from the interface vicinity region 71. Therefore, the minute particles P2 in the interface vicinity region 71 are not moved in the direction running along the flow unless another great force acts.

As shown in FIG. 11, in the interface vicinity region 171, interference fringes 175 can be observed by the naked eye due to a thickness difference in the water liquid film 50. The interference fringes 175 are contour lines.

As described above, the minute particles P2 are not moved in the direction F running along the flow (see FIG. 11) but can be moved in the tangent directions D1, D2 of the interference fringes 175. In the interface vicinity region 171, the minute particles P2 are disposed side by side in line along the tangent directions D1, D2 of the interference fringes 175. In other words, the minute particles P2 are disposed side by side along the line of the gas-liquid-solid interface 160. The minute particles P2 make a line for each size of the particles P themselves. Minute particles P21 having relatively large diameters are disposed further radially outward of minute particles P22 having relatively small diameters.

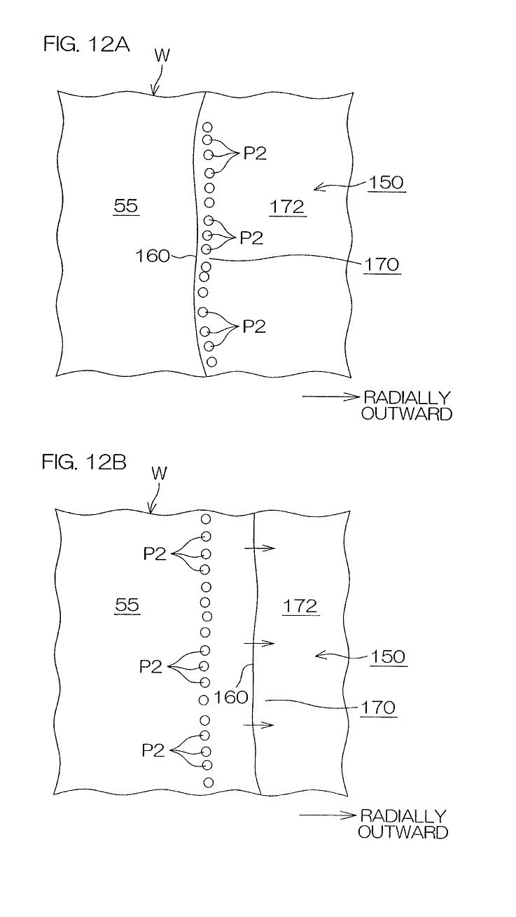

FIGS. 12A, 12B are plan views showing states of the inner peripheral portion 170 of the water liquid film during expansion of the liquid film removed region 55, according to the reference mode.

FIG. 12A shows a state where the minute particles P2 are contained in the inner peripheral portion 170 of the water liquid film (specifically, in the second portion 170B shown in FIG. 10). The minute particles P2 are disposed side by side along the line of the gas-liquid-solid interface 160.

As shown in FIG. 12B, when the gas-liquid-solid interface 160 is moved radially outward of the substrate W (in the direction of moving toward the bulk 172) in accordance with the expansion of the liquid film removed region 55, in the interface vicinity region 171, the heat convection 176 (see FIG. 9) flowing from the side of the bulk 172 to the side of the gas-liquid-solid interface 160 has been generated. Thus, force of pushing radially inward acts on the minute particles P2. In accordance with the expansion of the liquid film removed region 55, the gas-liquid-solid interface 160 is moved radially outward of the substrate W (in the direction of moving toward the bulk 172). However, the minute particles P2 cannot be moved in the radial direction (in the direction running along the flow). Thus, even when the gas-liquid-solid interface 160 is moved, the minute particles P2 are not moved. Therefore, the minute particles P2 contained in the interface vicinity region 71 are moved from the gas-liquid-solid interface 60 to the liquid film removed region 55 and precipitated on the liquid film removed region 55. The minute particles P2 remain on the upper surface of the substrate W after the water liquid film 50 is removed.

The present invention can also be applied to a batch type substrate processing apparatus.

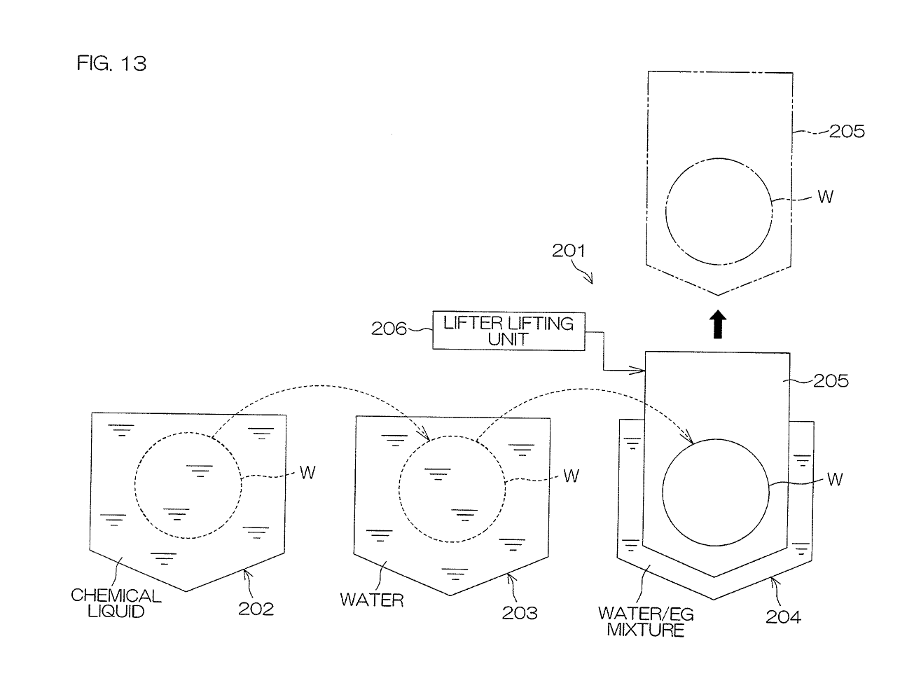

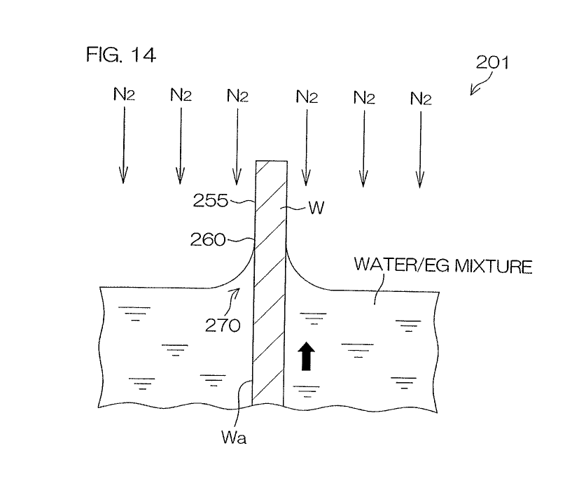

FIG. 13 is a schematic view for describing a general arrangement of a substrate processing apparatus 201 according to a second preferred embodiment of the present invention. FIG. 14 is a schematic view showing a state of pull-up and drying in the substrate processing apparatus 201.

The substrate processing apparatus 201 is a batch type substrate processing apparatus that processes plural substrates W in batch processing. The substrate processing apparatus 201 includes a chemical liquid storage tank 202 that stores a chemical liquid, a water storage tank 203 that stores water, a water/EG mixture storage tank 204 that stores a water/EG mixture, a lifter 205 that immerses the substrates W in the water/EG mixture stored in the water/EG mixture storage tank 204, and a lifter lifting unit 206 arranged to elevate and lower the lifter 205. At this time, concentration of EG of the water/EG mixture stored in the water/EG mixture storage tank 204 is set to be a predetermined concentration within a range of, for example, 1 weight % or more and less than 20 weight %.

The lifter 205 supports the plural substrates W in a vertical posture. The lifter lifting unit 206 elevates and lowers the lifter 205 between a processing position where the substrates W held by the lifter 205 are placed in the water/EG mixture storage tank 204 (position shown by a solid line in FIG. 13) and a retract position where the substrates W held by the lifter 205 are placed above the water/EG mixture storage tank 204 (position shown by a double chain line in FIG. 13).

In a series of processing in the substrate processing apparatus 201, the plural substrates W carried into a processing unit of the substrate processing apparatus 201 are immersed into the chemical liquid stored in the chemical liquid storage tank 202. Thereby, chemical liquid processing (cleaning processing or etching processing) is performed for the substrates W. When a predetermined time period elapses after the start of the immersion into the chemical liquid, the plural substrates W are pulled up from the chemical liquid storage tank 202 and transferred to the water storage tank 203. Next, the plural substrates W are immersed into the water stored in the water storage tank 203. Thereby, rinse processing is performed for the substrates W. When a predetermined time period elapses after the start of the immersion into the water, the substrates W are pulled up from the water storage tank 203 and transferred to the water/EG mixture storage tank 204.

By then controlling the lifter lifting unit 206 to move the lifter 205 from the retract position to the processing position, the plural substrates W held by the lifter 205 are immersed into the water/EG mixture. Thereby, the water/EG mixture is supplied to front surfaces (the surfaces to be processed: the pattern forming surfaces in the present preferred embodiment) Wa of the substrates W, and the water attached to the front surfaces Wa of the substrates W is replaced with the water/EG mixture (mixture replacing step). When a predetermined time period elapses after the start of the immersion of the substrates W into the water/EG mixture, the lifter lifting unit 206 is controlled to move the lifter 205 from the processing position to the retract position. Thereby, the plural substrates W immersed into the water/EG mixture are pulled up from the water/EG mixture.

At the time of pulling the substrates W up from the water/EG mixture, the pull-up and drying (mixture removing step) is performed. As shown in FIG. 14, the pull-up and drying is performed by pulling the substrates W up at relatively slow speed (for example, a few mm/second) while blowing inert gas (for example, nitrogen gas) to the front surfaces Wa of the substrates W pulled up from the water/EG mixture storage tank 204.

When some of the substrates W are pulled up from the water/EG mixture in a state where the substrates W are immersed in the water/EG mixture, the front surfaces Wa of the substrates W are exposed to the atmosphere. Thereby, liquid removed regions 255 from which the water/EG mixture is removed are formed on the front surfaces Wa of the substrates W. By further pulling the substrates W up from this state, the liquid removed regions 255 are expanded. By the expansion of the liquid removed regions 255, gas-liquid-solid interfaces 260 of the water/EG mixture between the liquid removed regions 255 and the front surfaces Wa of the substrates W are moved downward. In a state where the substrates Ware completely pulled up from the water/EG mixture, the liquid removed regions 255 are expanded over the entire substrates W. After the formation of the liquid remove regions 255, inside interface vicinity portions 270 of the water/EG mixture, an EG concentration gradient is formed due to the evaporation of the water at the gas-liquid-solid interfaces 260. Thereby, Marangoni convection flowing downward from the gas-liquid-solid interfaces 260 is generated.

Therefore, minute particles contained in the water/EG mixture receive the Marangoni convection and move in the direction of separating from the gas-liquid-solid interfaces 260 (that is, downward). Therefore, the minute particles are taken into the water/EG mixture stored in the water/EG mixture storage tank 204. All the substrates W are pulled up from the water/EG mixture without the minute particles appearing on the liquid removed regions 255, and the entire front surfaces Wa of the substrates W are dried. Therefore, the entire upper surfaces of the substrates W can be dried while reducing or preventing generation of the minute particles.

At the time of the pull-up and drying, the EG concentration can be maintained high at the gas-liquid-solid interfaces 260. Since surface tension of the EG is lower than that of the water, pattern collapse of the front surfaces of the substrates W after drying can be suppressed.

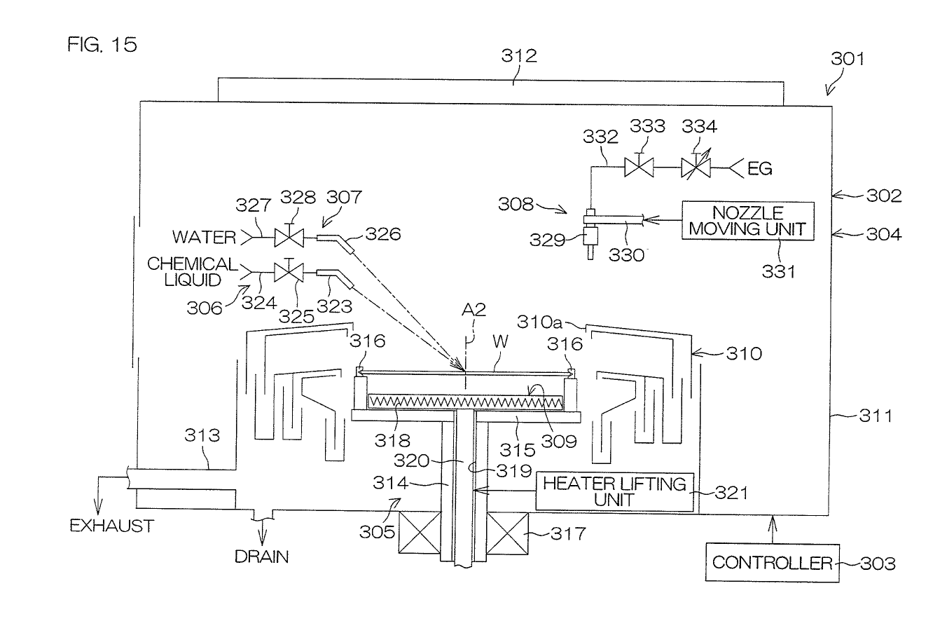

FIG. 15 is an illustrative sectional view for describing an arrangement example of a processing unit 302 provided in a substrate processing apparatus 301 according to a third preferred embodiment of the present invention.

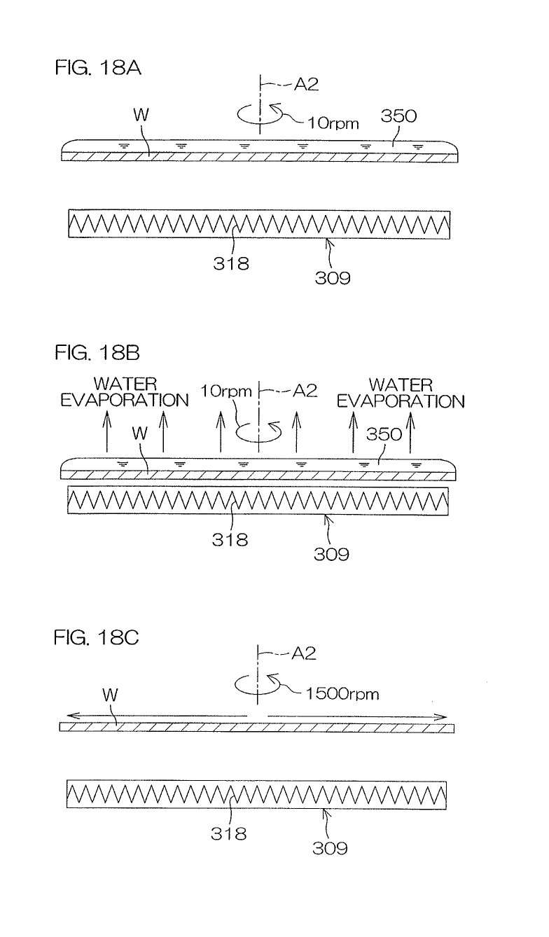

The processing unit 302 includes a box-shaped processing chamber 304, a spin chuck (substrate holding unit) 305 that holds a single substrate W in a horizontal posture in the processing chamber 304 and rotates the substrate W about the vertical rotational axis A2 passing through a center of the substrate W, a chemical liquid supplying unit 306 arranged to supply a chemical liquid to an upper surface of the substrate W which is held by the spin chuck 305, a water supplying unit (processing liquid supplying unit) 307 arranged to supply water serving as an example of a processing example to the upper surface of the substrate W which is held by the spin chuck 305, an EG supplying unit (low surface tension liquid supplying unit) 308 that supplies ethylene glycol (hereinafter, referred to as “EG”) serving as an example of a low surface tension liquid having the higher boiling point than that of the water (processing liquid) and lower surface tension than that of the water (processing liquid) to the upper surface (front surface) of the substrate W, a hot plate (heating unit) 309 disposed to face a lower surface of the substrate W which is held by the spin chuck 305, the hot plate being arranged to heat a water/EG mixture liquid film (hereinafter, referred to as “mixture liquid film”) 350 (see FIG. 18B, etc.) formed on the upper surface of the substrate W from the lower side via the substrate W, and a cylindrical processing cup 310 surrounding the spin chuck 305.

The processing chamber 304 includes a box-shaped partition wall 311, an FFU (fan filter unit) 312 serving as a blower unit that feeds clean air from an upper portion of the partition wall 311 to the inside of the partition wall 311 (corresponding to an interior of the processing chamber 304), and an exhaust apparatus (not shown) that exhausts gas in the processing chamber 304 from a lower portion of the partition wall 311.

The FFU 312 is disposed above the partition wall 311 and attached to a ceiling of the partition wall 311. The FFU 312 feeds clean air to the interior of the processing chamber 304 from the ceiling of the partition wall 311. The exhaust apparatus is connected to a bottom portion of the processing cup 310 via an exhaust duct 313 connected to an interior of the processing cup 310, and suctions the interior of the processing cup 310 from the bottom portion of the processing cup 310. A down flow (downward flow) is formed in the processing chamber 304 by the FFU 312 and the exhaust apparatus.

As the spin chuck 305, a clamping type chuck that clamps the substrate W in the horizontal direction to hold the substrate W horizontally is adopted. Specifically, the spin chuck 305 includes a vertically-extending cylindrical spin shaft 314, a disk-shaped spin base 315 attached to an upper end of the spin shaft 314 in a horizontal posture, plural (not less than three; for example, six) clamping pins 316 disposed at equal intervals in the spin base 315, and a spin motor 317 coupled to the spin shaft 314. The plural clamping pins 316 are disposed at suitable intervals, for example, at equal intervals on a circumference corresponding to an outer peripheral shape of the substrate W in a peripheral edge portion of an upper surface of the spin base 315. Each of the plural clamping pins 316 is an upward clamping pin (clamping pin whose lower portion is supported), to be displaced between a clamping position where the clamping pin is abutted with a peripheral edge portion of the substrate W to clamp the substrate W, and an open position further radially outward of the clamping position with respect to the substrate W. With the spin chuck 305, by abutting the clamping pins 316 with the peripheral edge portion of the substrate W to clamp the substrate, the substrate W is strongly held by the spin chuck 305. A drive mechanism (not shown) arranged to displace the clamping pins 316 is combined with the clamping pins 316. As clamping members, downward clamping pins (clamping pins whose upper portions are supported) may be adopted in place of the clamping pins 316.

The spin motor 317 is, for example, an electric motor. By transmitting rotational drive force from the spin motor 317 to the spin shaft 314, the substrate W held by the clamping pins 316 is rotated about the vertical rotation axis A2 passing through the center of the substrate W integrally with the spin base 315.

The hot plate 309 is formed in a disk shape having a horizontally flat front surface, for example, and has an outer diameter which is similar to an outer diameter of the substrate W. A circular upper surface of the hot plate 309 faces the lower surface (rear surface) of the substrate W held by the spin chuck 305. The hot plate 309 is disposed in a horizontal posture between the upper surface of the spin base 315 and the lower surface of the substrate W held by the spin chuck 305. The hot plate 309 is formed by using ceramics and silicon carbide (SiC), and a heater 318 is embedded inside. The entire hot plate 309 is warmed up by heating of the heater 318, so that the hot plate 309 functions to heat the substrate W. Over the entire upper surface of the hot plate 309, a heat generation amount per unit area of the upper surface in a state where the heater 318 is turned on is set to be uniform. The hot plate 309 is supported by a support rod 320 inserted through a through hole 319 which passes through the spin base 315 and the spin shaft 314 in the up and down direction in the vertical direction along the rotation axis A2 (in the thickness direction of the spin base 315). A lower end of the support rod 320 is fixed to a peripheral member below the spin chuck 305. The hot plate 309 is not coupled to the spin motor 317. Thus, even when the substrate W is rotated, the hot plate 309 is not rotated but remains stationary (in a non-rotation state).

A heater lifting unit 321 arranged to elevate and lower the hot plate 309 is combined with the support rod 320. The hot plate 309 is elevated and lowered while maintaining its horizontal posture by the heater lifting unit 321. The heater lifting unit 321 is formed by, for example, a ball screw or a motor. By drive of the heater lifting unit 321, the hot plate 309 is elevated and lowered between a lower position where the hot plate is separated from the lower surface of the substrate W held by the spin chuck 305 (see FIG. 18A, etc.), and an upper position where the hot plate comes close to the lower surface of the substrate W held by the spin chuck 305 with a minute gap (see FIG. 18B).

In a state where the upper surface of the hot plate 309 is placed at the upper position, the gap between the lower surface of the substrate W and the upper surface of the hot plate 309 is set to be, for example, about 0.3 mm. In a state where the upper surface of the hot plate 309 is placed at the lower position, the gap between the lower surface of the substrate W and the upper surface of the hot plate 309 is set to be, for example, about 10 mm. In such a way, the gap between the hot plate 309 and the substrate W can be changed.

The chemical liquid supplying unit 306 includes a chemical liquid nozzle 323. The chemical liquid nozzle 323 is, for example, a straight nozzle that discharges a liquid in a state of a continuous stream and is disposed fixedly above the spin chuck 305 with its discharge port directed at a central portion of the upper surface of the substrate W. A chemical liquid piping 324 to which chemical liquid from a chemical liquid supply source is supplied is connected to the chemical liquid nozzle 323. A chemical liquid valve 325 arranged to switch between supply/stop of supply of the chemical liquid from the chemical liquid nozzle 323 is interposed in an intermediate portion of the chemical liquid piping 324. When the chemical liquid valve 325 is opened, the chemical liquid of continuous stream supplied from the chemical liquid piping 324 to the chemical liquid nozzle 323 is discharged from the discharge port set in a lower end of the chemical liquid nozzle 323. When the chemical liquid valve 325 is closed, the supply of the chemical liquid from the chemical liquid piping 324 to the chemical liquid nozzle 323 is stopped.

Specific examples of the chemical liquid are an etching liquid and a cleaning liquid. More specifically, the chemical liquid may be hydrofluoric acid, SC1 (ammonia/hydrogen peroxide mixture), SC2 (hydrochloric acid/hydrogen peroxide mixture), ammonium fluoride, buffered hydrogen fluoride (mixture of hydrofluoric acid and ammonium fluoride), etc.

The water supplying unit 307 includes a water nozzle 326. The water nozzle 326 is, for example, a straight nozzle that discharges a liquid in a state of a continuous stream and is disposed fixedly above the spin chuck 305 with its discharge port directed at the central portion of the upper surface of the substrate W. A water piping 327 to which water from a water supply source is supplied is connected to the water nozzle 326. A water valve 328 arranged to switch between supply/stop of supply of the water from the water nozzle 326 is interposed in an intermediate portion of the water piping 327. When the water valve 328 is opened, the water of continuous stream supplied from the water piping 327 to the water nozzle 326 is discharged from the discharge port set in a lower end of the water nozzle 326. When the water valve 328 is closed, the supply of the water from the water piping 327 to the water nozzle 326 is stopped. The water is, for example, deionized water (DIW). However, the water of the present invention is not limited to DIW but may be any of carbonated water, electrolyzed ion water, hydrogen water, ozone water, and aqueous hydrochloric acid solution of dilute concentration (for example, of about 10 ppm to 100 ppm). The boiling point of the water (DIW) is 100° C. and surface tension is 72.75 at an ordinary temperature.

Each of the chemical liquid nozzle 323 and the water nozzle 326 does not need to be disposed fixedly with respect to the spin chuck 305. For example, a so-called scanning nozzle mode in which the nozzle is attached to an arm swingable in a horizontal plane above the spin chuck 305 and a liquid landing position of the processing liquid (the chemical liquid or the water) on the upper surface of the substrate W is scanned by swinging of the arm may be adopted.

The EG supplying unit 308 includes an EG nozzle 329 arranged to discharge the EG, a first nozzle arm 330 in which the EG nozzle 329 is attached to a tip portion, and a first nozzle moving unit 331 that moves the EG nozzle 329 by moving the first nozzle arm 330. The EG nozzle 329 is, for example, a straight nozzle that discharges the EG in a state of a continuous stream and is attached to the horizontally extending first nozzle arm 330 with its discharge port directed downward for example.

The EG supplying unit 308 also includes an EG piping 332 connected to the EG nozzle 329 to supply the EG from an EG supply source to the EG nozzle 329, an EG valve 333 arranged to switch supply/stop of supply of the EG from the EG nozzle 329, and a first flow rate regulation valve 334 arranged to adjust an opening degree of the EG piping 332 to regulate a flow rate of the EG discharged from the EG nozzle 329. The first flow rate regulation valve 334 includes a valve body (not shown) inside which a valve seat is provided, a valve element that opens and closes the valve seat, and an actuator (not shown) that moves the valve element between an open position and a close position. The same applies to the other flow rate regulation valves. The boiling point of the EG is 197.5° C. and surface tension is 47.3 at an ordinary temperature. That is, the EG is a liquid having the higher boiling point than that of the water and lower surface tension than that of the water.

As shown in FIG. 15, the processing cup 310 is disposed further outward of the substrate W held by the spin chuck 305 (in the direction of separating from the rotation axis A2). The processing cup 310 surrounds the spin base 315. When the processing liquid is supplied to the substrate W in a state where the spin chuck 305 rotates the substrate W, the processing liquid supplied to the substrate W is spun off to a periphery of the substrate W. When the processing liquid is supplied to the substrate W, an upper end portion 310a of the upward-opening processing cup 310 is disposed higher than the spin base 315. Therefore, the processing liquid discharged to the periphery of the substrate W such as the chemical liquid and the water is received by the processing cup 310. The processing liquid received by the processing cup 310 is fed to a recovery apparatus or a draining apparatus (not shown).

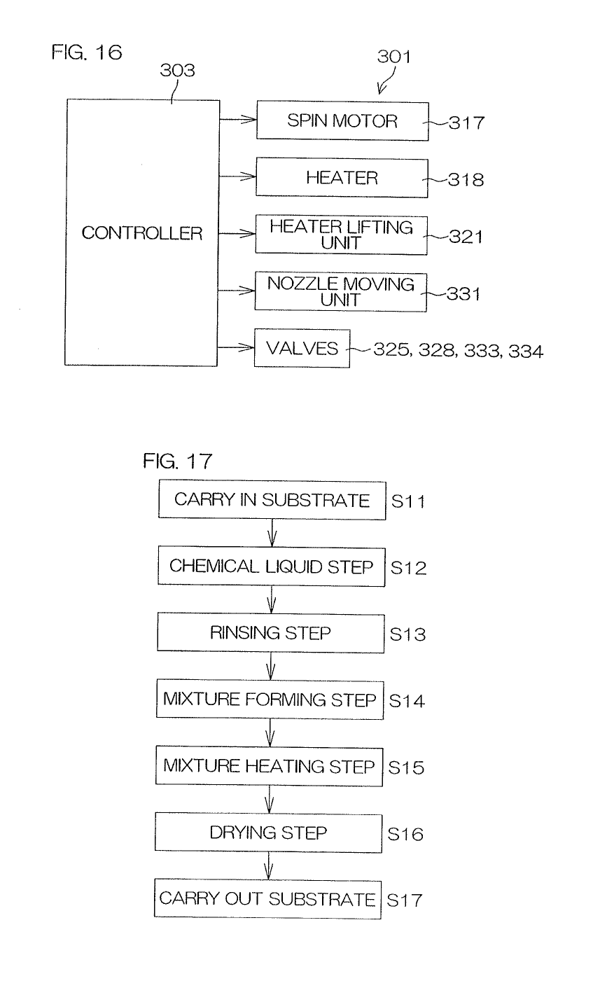

FIG. 16 is a block diagram for describing an electrical arrangement of a main portion of the substrate processing apparatus 301.

A controller 303 controls operations of the spin motor 317, the heater lifting unit 321, and the first nozzle moving unit 331, etc., in accordance with a predetermined program. The controller 303 also controls opening and closing operations, etc., of the chemical liquid valve 325, the water valve 328, the EG valve 333, and the first flow rate regulation valve 334, etc. Further, the controller 303 controls turning on/off of the heater 318.

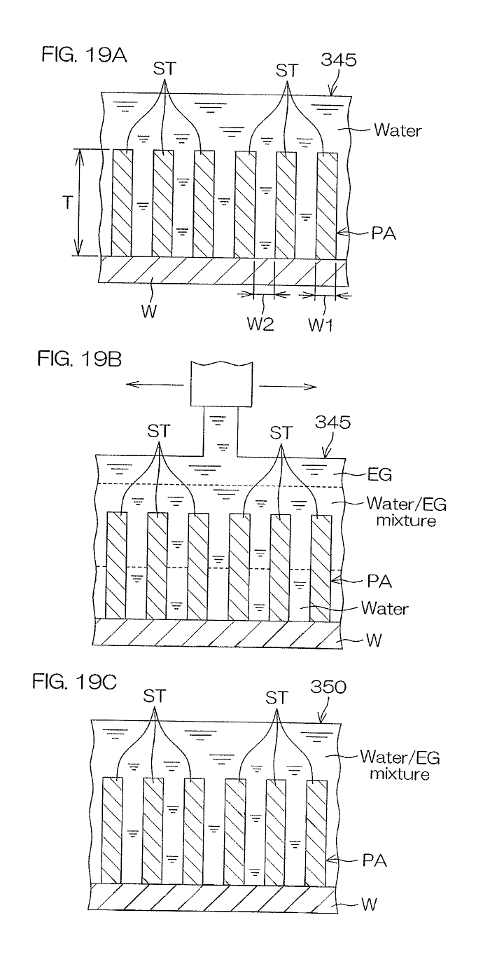

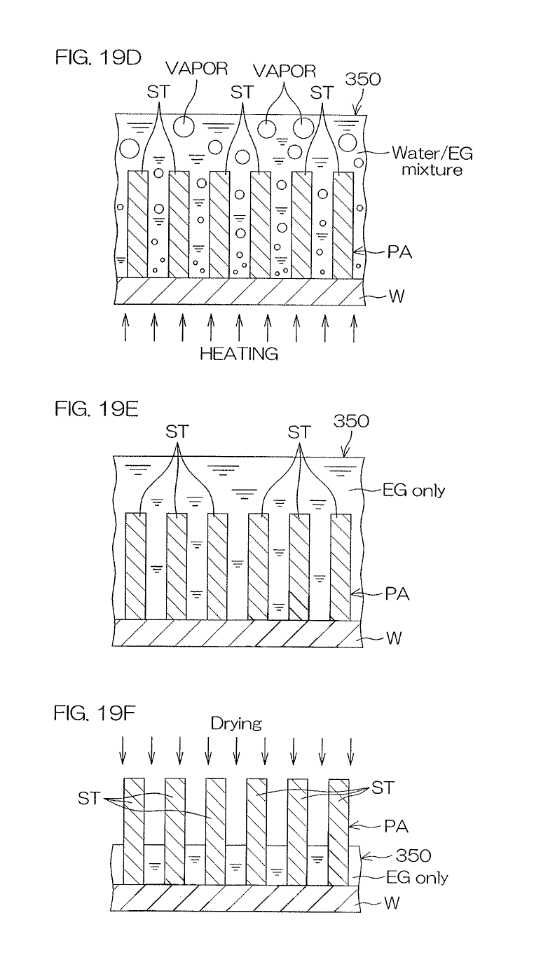

FIG. 17 is a flowchart for describing an example of substrate processing performed by the substrate processing apparatus 301. FIGS. 18A to 18C are illustrative sectional views for describing states of a mixture forming step (S14 of FIG. 17), a mixture heating step (S15 of FIG. 17), and a drying step (S16 of FIG. 17). FIGS. 19A to 19F are illustrative sectional views showing states of the front surface of the substrate W in a rinsing step (S13 of FIG. 17), the mixture forming step (S14 of FIG. 17), the mixture heating step (S15 of FIG. 17), and the drying step S16 of FIG. 17). With reference to FIGS. 15 to 19F, the substrate processing will be described.

The unprocessed substrate W is carried into the processing unit 302 from the carrier C by the transfer robots IR, CR and carried into the interior of the processing chamber 304, the substrate W is delivered to the spin chuck 305 in a state where the front surface (the surface to be processed: the pattern forming surface in the present preferred embodiment) of the substrate is directed upward, and the substrate W is held by the spin chuck 305 (S11: substrate carry-in step (substrate holding step)). Before carrying in the substrate W, the EG nozzle 329 is retracted to a home position set on the side of the spin chuck 305. The hot plate 309 is disposed at the lower position where the hot plate is separated from the lower surface of the substrate W. At this time, the heater 318 is off.

After the transfer robot CR is retracted out of the processing unit 302, the controller 303 controls the spin motor 317 to start the rotation of the substrate W and accelerate the rotation to a predetermined liquid processing rotational speed (for example, about 800 rpm).

The controller 303 turns on the heater 318. Thereby, the heater 318 generates heat and a temperature of the upper surface of the hot plate 309 is increased to a predetermined fixed temperature. The front surface of the hot plate 309 is brought into a high temperature state by turning on the heater 318. However, since the hot plate 309 is disposed at the lower position, the substrate W is hardly warmed up by the heat from the hot plate 309.

Next, the controller 303 executes a chemical liquid step (Step S12). Specifically, after the rotational speed of the substrate W reaches the liquid processing speed, the controller 303 opens the chemical liquid valve 325. Thereby, the chemical liquid is supplied from the chemical liquid nozzle 323 toward the upper surface of the rotating substrate W. The supplied chemical liquid is spread over the entire surface of the substrate W by centrifugal force, and chemical liquid processing using the chemical liquid is performed for the substrate W. When a predetermined time period elapses after the start of the discharge of the chemical liquid, the controller 303 closes the chemical liquid valve 325 to stop the discharge of the chemical liquid from the chemical liquid nozzle 323.

Next, the controller 303 executes a rinsing step (Step S13). The rinsing step (S13) is a step of replacing the chemical liquid on the substrate W with the water to remove the chemical liquid from the top of the substrate W. Specifically, the controller 303 opens the water valve 328. Thereby, the water is supplied from the water nozzle 326 toward the upper surface of the rotating substrate W. The supplied water is spread over the entire surface of the substrate W by the centrifugal force. By the water, the chemical liquid attached to the top of the substrate W is washed away.

When a predetermined time period elapses after the start of the supply of the water, in a state where the entire upper surface of the substrate W is covered with the water, the controller 303 controls the spin motor 317 to stepwise reduce the rotational speed of the substrate W from the liquid processing speed to puddle speed (zero or a low rotational speed of about 40 rpm or less, for example, about 10 rpm). After that, the rotational speed of the substrate W is maintained at the puddle speed. Thereby, a water liquid film covering the entire upper surface of the substrate W is supported in a puddle shape on the upper surface of the substrate W. In this state, the centrifugal force acting on the water liquid film on the upper surface of the substrate W is smaller than the surface tension acting between the water and the upper surface of the substrate W, or the above-described centrifugal force is substantially balanced with the above-described surface tension. By the speed reduction of the substrate W, the centrifugal force acting on the water on the substrate W is weakened, and an amount of the water discharged from the top of the substrate W is reduced. Thereby, as shown in FIG. 19A, a puddle-shaped water liquid film 345 is formed on the upper surface of the substrate W. After that, the rotational speed of the substrate W is maintained at the puddle speed. The supply of the water to the substrate W is stopped after the formation of the water liquid film 345. However, after the formation of the puddle-shaped water liquid film, the supply of the water to the substrate W may be continued.

Next, the mixture forming step (Step S14 of FIG. 17) is executed.

Specifically, when a predetermined time period elapses after the speed reduction of the substrate W, the controller 303 controls the first nozzle moving unit 331 to move the EG nozzle 329 from the home position to a processing position above the substrate W. After that, the controller 303 opens the EG valve 333 to discharge the EG from the EG nozzle 329 toward the upper surface of the substrate W. Further, the controller 303 moves an EG supply position to the upper surface of the substrate W between the central portion and the peripheral edge portion. Thereby, the water supply position scans through the entire upper surface of the substrate W, and the EG is directly applied to the entire upper surface of the substrate W. For a while after the start of the discharge of the EG, the EG is not sufficiently spread inside the liquid film 345. As a result, as shown in FIG. 19B, the EG is accumulated in a surface layer portion of the liquid film 345, and the water is accumulated in a base layer portion of the liquid film 345. In this state, in the liquid film 345, a mixture of the water and the EG (hereinafter, referred to as “water/EG mixture”) is formed only in an intermediate portion between the surface layer portion and the base layer portion. After that, with the elapse of time, the EG is spread over the entire liquid film 345, and the entire water liquid film 345 is replaced with the water/EG mixture. That is, a mixture liquid film 350 is formed on the upper surface of the substrate W (see FIG. 18A and FIG. 19C).

Next, the controller 303 executes the mixture heating step (Step S15 of FIG. 17).

Specifically, the controller 303 controls the heater lifting unit 321 to elevate the hot plate 309 from the lower position (see FIG. 18A, etc.) to the upper position as shown in FIG. 18B. By disposing the hot plate 309 at the upper position, the substrate W is heated by heat radiation from the upper surface of the hot plate 309 that is at the upper position. Since the substrate W is heated to have a high temperature, the mixture liquid film 350 on the upper surface of the substrate W is also heated to have a high temperature which is substantially equal to the temperature of the substrate W. A temperature at which the mixture liquid film 350 is heated is set to be a predetermined high temperature (for example, about 150° C.) which is higher than the boiling point of the water and lower than the boiling point of the EG.

By heating the mixture liquid film 350, as shown in FIG. 19D, the water contained in the mixture liquid film 350 is boiled and the water is evaporated from the mixture liquid film 350. As a result, the water is completely removed from the mixture liquid film 350, and as shown in FIG. 19E, the liquid film contains only the EG. That is, an EG liquid film 351 is formed on the upper surface of the substrate W. Thereby, the water on the upper surface of the substrate W can be completely replaced with the EG.

When a predetermined time period elapses after the elevation of the hot plate 309, as shown in FIG. 18C, the controller 303 controls the heater lifting unit 321 to lower the position of the hot plate 309 from the upper position (see FIG. 18B) to the lower position. Thereby, the heating of the substrate W by the hot plate 309 is ended.

Next, the controller 303 controls the spin motor 317 to increase the rotational speed of the substrate W to spin-off drying speed (for example, 1,500 rpm) as shown in FIG. 18C. Thereby, the EG liquid film 351 on the upper surface of the substrate W is spun off and the substrate W is dried (spin drying, S16 of FIG. 17: drying step). In the drying step (S16), as shown in FIG. 19F, the EG is removed from between structures ST of a pattern PA. Since the EG has lower surface tension than that of the water, pattern collapse in the drying step (S16) can be suppressed.

When a predetermined time period elapses after the start of the drying step (S16), the controller 303 controls the spin motor 514 to stop the rotation of the spin chuck 305. The controller 303 also turns off the heater 318. After that, the transfer robot CR enters the processing unit 302 and carries the processed substrate W out of the processing unit 302 (Step S17 of FIG. 17). The substrate W is delivered from the transfer robot CR to the transfer robot IR, and housed in the carrier C by the transfer robot IR.

As described above, according to the third preferred embodiment, the EG is supplied to the water liquid film 345 of the substrate W. Thereby, the water and the EG are mixed, and the mixture liquid film 350 is formed on the upper surface of the substrate W. By heating the mixture liquid film 350, the water contained in the mixture liquid film 350 is evaporated. As a result, the water in the mixture liquid film 350 can be completely replaced with the EG.

The mixture liquid film 350 is formed by the supply of the EG and the water contained in the mixture liquid film 350 is evaporated, so that only the EG remains. Thus, speed to replace the water with the EG can be increased. Thereby, the water on the upper surface of the substrate W can be completely replaced with the EG in a short time. Therefore, the upper surface of the substrate W can be dried in a short time while reducing collapse of the pattern PA. Thereby, a drying time of the substrate W can be shortened and a use amount of the EG can be reduced.

In the mixture heating step (S15 of FIG. 17), the temperature at which the mixture liquid film 350 is heated is set to be the predetermined high temperature (for example, about 150° C.) which is higher than the boiling point of the water and lower than the boiling point of the EG. Therefore, although the EG in the water/EG mixture is hardly evaporated, the evaporation of the water in the water/EG mixture is facilitated. That is, only the water in the mixture liquid film 350 can be efficiently evaporated. Thereby, complete replacement by the low surface tension liquid can be realized in a further short time.

The temperature at which the mixture liquid film 350 is heated is lower than the boiling point of the EG. Thus, after the mixture heating step (S15 of FIG. 17), the EG liquid film having a predetermined thickness can beheld on the upper surface of the substrate W.

By forming the puddle-shaped water liquid film 345 on the upper surface of the substrate W and supplying the EG to the water liquid film 345, the mixture liquid film 350 is formed on the upper surface of the substrate W. Thus, the discharge of the EG from the substrate W can be suppressed. Thereby, the use amount of the EG can be further reduced.

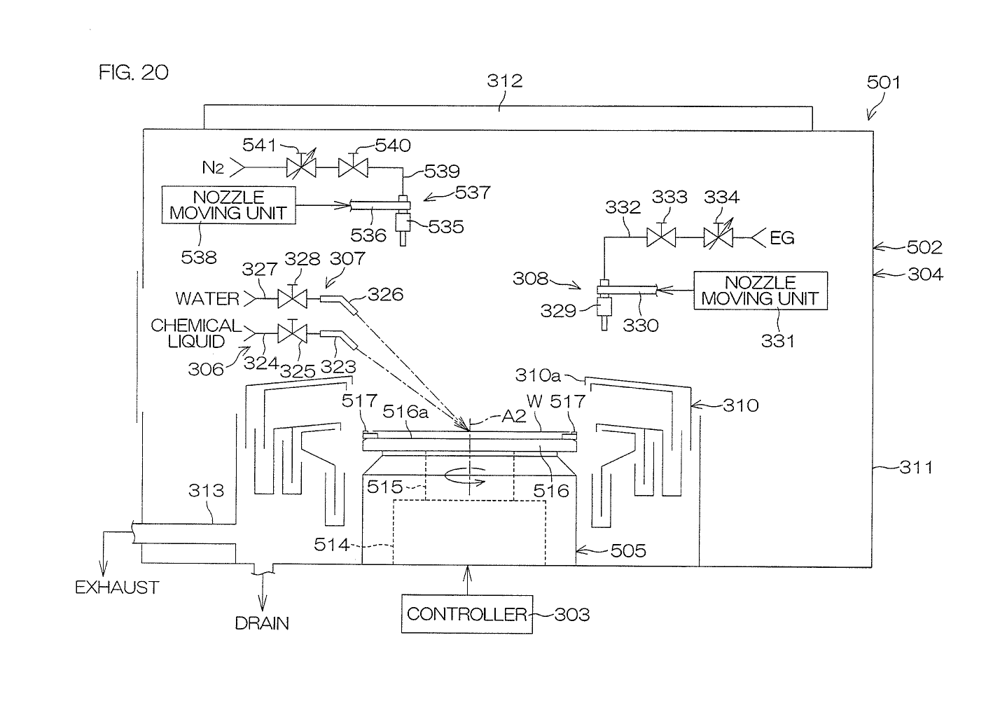

FIG. 20 is an illustrative sectional view for describing an arrangement example of a processing unit 502 provided in a substrate processing apparatus 501 according to a fourth preferred embodiment of the present invention.

In the fourth preferred embodiment, portions corresponding to the respective portions indicated in the third preferred embodiment will be indicated with the same reference symbols as in FIG. 15 to FIG. 19F and description thereof will be omitted.

The processing unit 502 is different from the processing unit 302 according to the third preferred embodiment in a first main point that a spin chuck (substrate holding unit) 505 is provided in place of the spin chuck 305. That is, the processing unit 302 does not include the hot plate 309.

The processing unit 502 is different from the processing unit 302 according to the third preferred embodiment in a second main point that the processing unit further includes a gas unit 537 arranged to supply gas to an upper surface of a substrate W held by the spin chuck 505.

As the spin chuck 505, a clamping type chuck that clamps the substrate W in the horizontal direction to hold the substrate W horizontally is adopted. Specifically, the spin chuck 505 includes a spin motor 514, a spin shaft 515 integrated with a drive shaft of the spin motor 514, and a disk-shaped spin base 516 substantially horizontally attached to an upper end of the spin shaft 515.

The spin base 516 includes a horizontal and circular upper surface 516a having an outer diameter which is larger than an outer diameter of the substrate W. Plural (not less than three; for example, six) clamping members 517 are disposed in a peripheral edge portion of the upper surface 516a. In the upper surface peripheral edge portion of the spin base 516, the plural clamping members 517 are disposed at suitable intervals, for example, at equal intervals on a circumference corresponding to an outer peripheral shape of the substrate W.

The gas unit 537 includes a gas nozzle 535 that discharges nitrogen gas serving as an example of inert gas toward the upper surface of the substrate W, a second nozzle arm 536 in which the gas nozzle 535 is attached to a tip portion, and a second nozzle moving unit 538 that moves the gas nozzle 535 by moving the second nozzle arm 536. The gas nozzle 535 is attached to the horizontally extending second nozzle arm 536 with its discharge port directed downward for example.

A gas piping 539 to which a high-temperature inert gas (higher than an ordinary temperature, for example, of 30 to 300° C.) from an inert gas supply source is supplied is connected to the gas nozzle 535. A gas valve 540 arranged to switch between supply/stop of supply of the inert gas from the gas nozzle 535 and a second flow rate regulation valve 541 arranged to adjust an opening degree of the gas piping 539 to regulate a flow rate of the inert gas discharged from the gas nozzle 535 are interposed in an intermediate portion of the gas piping 539. When the gas valve 540 is opened, the inert gas supplied from the gas piping 539 to the gas nozzle 535 is discharged from the discharge port. When the gas valve 540 is closed, the supply of the inert gas from the gas piping 539 to the gas nozzle 535 is stopped. The inert gas is not limited to nitrogen gas but may be CDA (clean dry air).

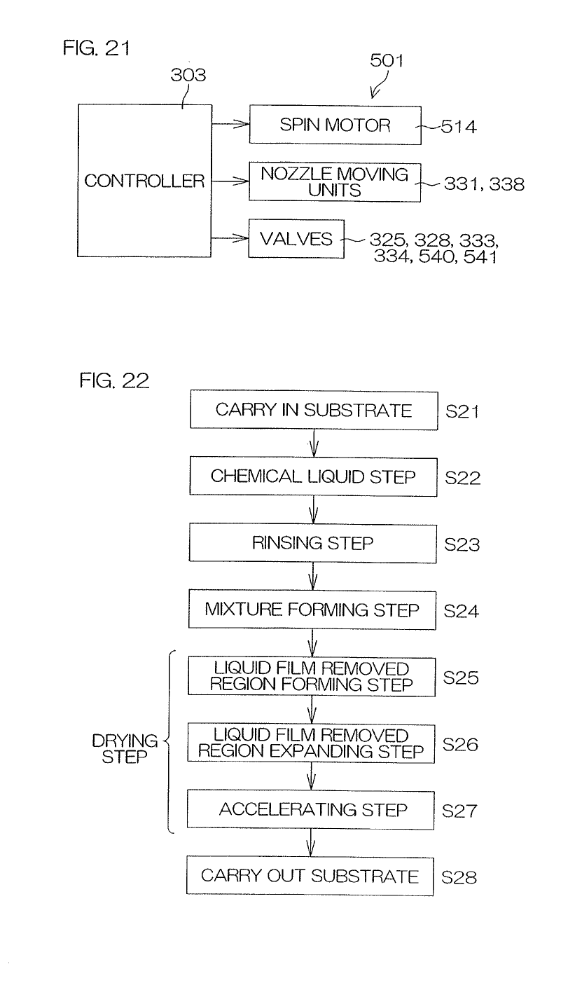

FIG. 21 is a block diagram for describing an electrical arrangement of a main portion of the substrate processing apparatus 501.

The controller 303 controls operations of the spin motor 514, the first and second nozzle moving units 331, 538, etc., in accordance with a predetermined program. Further, the controller 303 controls opening and closing operations, etc., of a chemical liquid valve 325, a water valve 328, an EG valve 333, the gas valve 540, the first and second flow rate regulation valves 334, 541, etc.

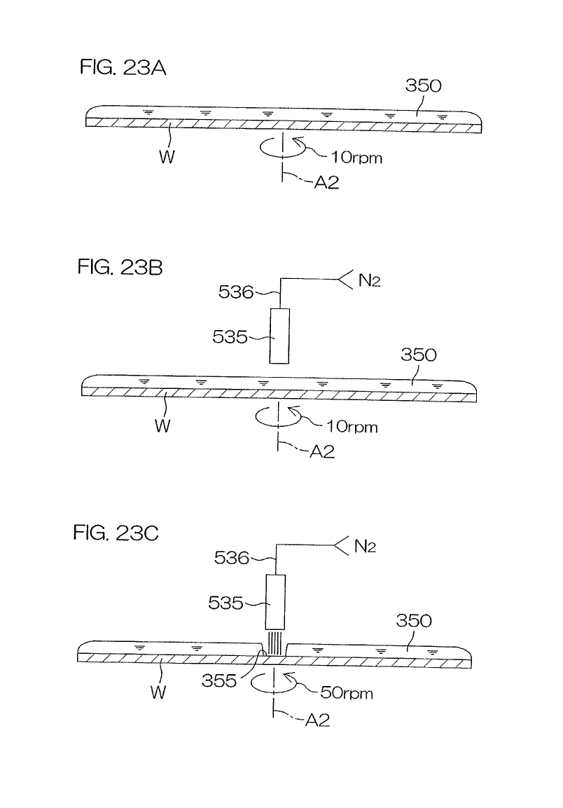

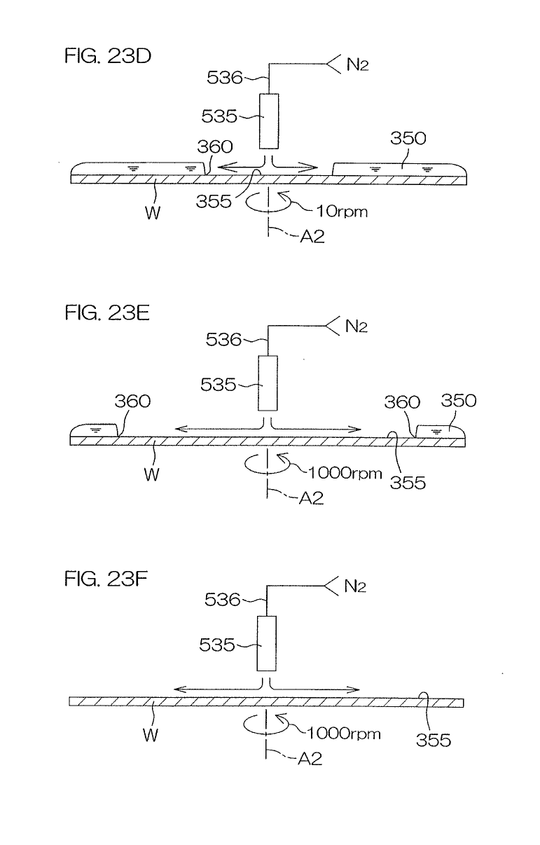

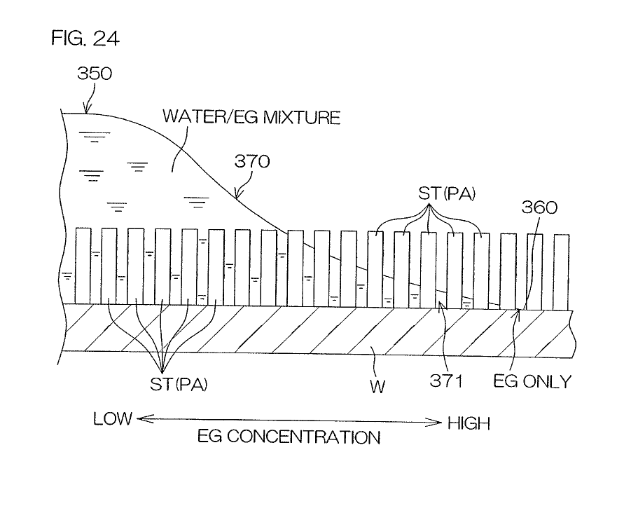

FIG. 22 is a flowchart for describing an example of substrate processing performed by the substrate processing apparatus 501. FIG. 23A to 23F are illustrative sectional views for describing states of a mixture forming step (S24 of FIG. 22), a liquid film removed region forming step (S25 of FIG. 22), and a liquid film removed region expanding step (S26 of FIG. 22). With reference to FIGS. 21 to 23F, the substrate processing performed by the substrate processing apparatus 501 will be described.

The unprocessed substrate W is carried into the interior of the processing chamber 504 by the transfer robots IR, CR, the substrate W is delivered to the spin chuck 505 in a state where the front surface (the surface to be processed: the pattern forming surface in the present preferred embodiment) of the substrate is directed upward, and the substrate W is held by the spin chuck 505 (S21: substrate carry-in step (substrate holding step)). Before carrying in the substrate W, an EG nozzle 329 and the gas nozzle 535 are retracted to home positions set on the side of the spin chuck 505.

After the transfer robot CR is retracted out of the processing unit 502, the controller 303 starts the rotation of the substrate W, and executes a chemical liquid step (Step S22), a rinsing step (Step S23), and the mixture forming step (Step S24) in order. The chemical liquid step (S22), the rinsing step (S23), and the mixture forming step (S24) are processes which are respectively similar to the chemical liquid step (Step S12), the rinsing step (Step S13), and the mixture forming step (Step S14) according to the third preferred embodiment. Thus, description thereof will be omitted.

In the mixture forming step (S24), a mixture liquid film 350 is formed on the upper surface of the substrate W (see FIG. 23A and FIG. 19C). Before the end of the mixture forming step (S24), the controller 303 controls the second nozzle moving unit 538 to dispose the gas nozzle 535 above the substrate W from the home position on the side of the spin chuck 505 as shown in FIG. 23B.

When a predetermined time period elapses after the start of the mixture forming step (S24), the controller 303 executes a drying step. In the drying step, the liquid film removed region forming step (S25), the liquid film removed region expanding step (S26), and an accelerating step (S27) are executed in this order. The liquid film removed region forming step (S25) is a step of forming a liquid film removed region 355 from which the mixture is removed in a central portion of the mixture liquid film 350. The liquid film removed region expanding step (S26) is a step of expanding the liquid film removed region 355 over the entire upper surface of the substrate W.

In the liquid film removed region forming step (S25), the controller 303 opens the gas valve 540 to discharge the inert gas from the gas nozzle 535 toward the central portion of the upper surface of the substrate W (gas blowing step), and controls the spin motor 514 to accelerate the substrate W to a predetermined hole making speed (for example, about 50 rpm) (high speed rotating step). By blowing the inert gas to the central portion of the mixture liquid film 350 on the upper surface of the substrate W, the water/EG mixture in the central portion of the mixture liquid film 350 is blown away and removed from the central portion of the upper surface of the substrate W by blowing pressure (gas pressure). By the rotational speed of the substrate W reaching the above-described hole making speed (for example, about 50 rpm), a relatively strong centrifugal force acts on the mixture liquid film 350 on the substrate W. Thereby, as shown in FIG. 23C, the circular liquid film removed region 355 is formed in the central portion of the upper surface of the substrate W. Although the hole making speed is set to be about 50 rpm, the hole making speed may be any rotational speed which is equal to or higher than the above-described speed. Next to the liquid film removed region forming step (S25), the liquid film removed region expanding step (S26) is executed.

In the liquid film removed region expanding step (S26), the controller 303 controls the spin motor 514 to increase the rotational speed of the substrate W to a predetermined first drying speed (for example, 1,000 rpm). In accordance with the increase in the rotational speed of the substrate W, the liquid film removed region 355 is expanded as shown in FIGS. 23D, 23E. By the expansion of the liquid film removed region 355, a gas-liquid-solid interface 360 of the mixture liquid film 350 between the liquid film removed region 355 and the upper surface of the substrate W is moved radially outward of the substrate W. As shown in FIG. 23F, by then expanding the liquid film removed region 355 over the entire substrate W, all the mixture liquid film 350 is discharged out of the substrate W.

After the liquid film removed region 355 is expanded over the entire upper surface of the substrate W, the liquid film removed region expanding step is ended. In accordance with the end of the liquid film removed region expanding step, the controller 303 closes the gas valve 540 to stop the discharge of the inert gas from the gas nozzle 535.

Next, the controller 303 executes the accelerating step (S27). Specifically, the controller 303 increases the rotational speed of the substrate W to about 1,500 rpm. Thereby, the upper surface of the substrate W is further dried.

When a predetermined time period elapses after the start of the accelerating step (S27), the controller 303 controls the spin motor 514 to stop the rotation of the spin chuck 305. After that, the transfer robot CR enters the processing unit 502 and carries the processed substrate W out of the processing unit 502 (Step S28). The substrate W is delivered from the transfer robot CR to the transfer robot IR, and housed in the carrier C by the transfer robot IR.

FIG. 23 is an expanded sectional view for describing an inner peripheral portion of the mixture liquid film 350.

After the formation of the liquid film removed region 355, the water having the low boiling point is mainly evaporated at the gas-liquid-solid interface 360. As a result, the EG concentration is increased. At this time, in an inner peripheral portion 370 of the mixture liquid film, such a concentration gradient that the EG concentration is lowered with distance from the gas-liquid-solid interface 360 is formed. In the present preferred embodiment, the EG concentration of the mixture liquid film 350 is fixed so that only the EG exists at the gas-liquid-solid interface 360 (that is, a supply amount of the EG in the mixture forming step (S24) is fixed). In this case, the water can be completely replaced with the EG at the gas-liquid-solid interface 360.

As described above, according to the present preferred embodiment, the EG is supplied to a water liquid film 345 of the substrate W. Thereby, the water and the EG are mixed, and the mixture liquid film 350 is formed on the upper surface of the substrate W.

The liquid film removed region 355 is formed in the mixture liquid film 350, and further, the liquid film removed region 355 is expanded until it covers the entire substrate W. On the upper surface of the substrate W, while the water/EG mixture is evaporated at the gas-liquid-solid interface 360 of the mixture liquid film 350, the liquid film removed region 355 is expanded. At the gas-liquid-solid interface 360, the water having the low boiling point is mainly evaporated. As a result, the EG concentration is increased. At this time, only the EG exists at the gas-liquid-solid interface 360, and in the inner peripheral portion 370 of the mixture liquid film, such a concentration gradient that the EG concentration is lowered with distance from the gas-liquid-solid interface 360 is formed. That is, at the gas-liquid-solid interface 360, the water can be completely replaced with the EG. It is considered that when the liquid is completely removed from between portions a pattern PA, surface tension of the liquid acts on the pattern PA. By completely replacing with the EG at the gas-liquid-solid interface 360, the surface tension acting on the pattern PA at the time of completely removing the liquid from the pattern PA can be suppressed to be low. Thus, collapse of the pattern PA can be suppressed.

The mixture liquid film 350 is formed by the supply of the EG and the water contained in the mixture liquid film 350 is evaporated, so that only the EG remains. Thus, speed to replace the water with the EG can be increased. Thereby, the water on the upper surface of the substrate W can be completely replaced with the EG in a short time. Therefore, the upper surface of the substrate W can be dried in a short time while reducing the collapse of the pattern PA. Thereby, a drying time of the substrate W can be shortened and a use amount of the EG can be reduced.

By supplying the high-temperature inert gas to the upper surface of the substrate W, the evaporation of the water at the gas-liquid-solid interface 360 of the mixture liquid film 350 can be facilitated. Thereby, complete replacement with the EG can be performed at the gas-liquid-solid interface 360 of the mixture liquid film 350.

By forming the puddle-shaped water liquid film 345 on the upper surface of the substrate W and supplying the EG to the water liquid film 345, the mixture liquid film 350 is formed on the upper surface of the substrate W. Thus, the discharge of the EG from the substrate W can be suppressed. Thereby, the use amount of the EG can be further reduced.

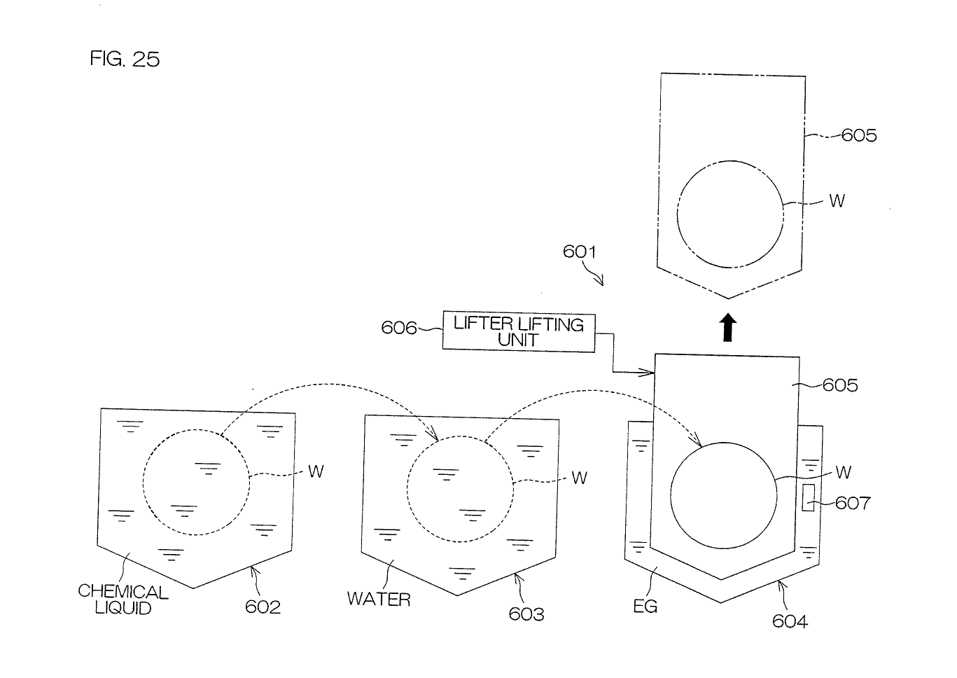

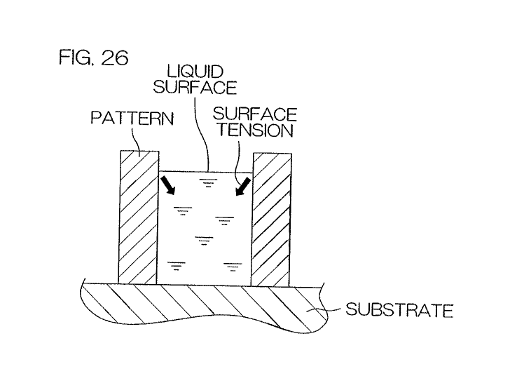

The present invention can also be applied to a batch type substrate processing apparatus. FIG. 25 is a schematic view for describing a general arrangement of a substrate processing apparatus 601 according to a fifth preferred embodiment of the present invention.

The substrate processing apparatus 601 is a batch type substrate processing apparatus that processes plural substrates W in batch processing. The substrate processing apparatus 601 includes a chemical liquid storage tank 602 that stores a chemical liquid, a water storage tank 603 that stores water, an EG storage tank 604 that stores an EG mixture, a lifter 605 that immerses the substrates W in the EG stored in the EG storage tank 604, and a lifter lifting unit 606 arranged to elevate and lower the lifter 605. The lifter 605 supports the plural substrates W in a vertical posture. The lifter lifting unit 606 elevates and lowers the lifter 605 between a processing position where the substrates W held by the lifter 605 are placed in the EG storage tank 604 (position shown by a solid line in FIG. 25) and a retract position where the substrates W held by the lifter 605 are placed above the EG storage tank 604 (position shown by a double chain line in FIG. 12).

A heater 607 that is immersed into the stored EG and heats the EG to adjust the temperature is provided in the EG storage tank 604. As the heater 607, a sheath heater can be taken as an example. A temperature meter (not shown) that measures a liquid temperature of the EG, a liquid amount sensor (not shown) that monitors a liquid amount in the EG storage tank 604, etc., are further provided in the EG storage tank 604. The liquid temperature of the EG stored in the EG storage tank 604 is regulated to be, for example, about 150° C.

In a series of processing in the substrate processing apparatus 601, the plural substrates W carried into a processing unit of the substrate processing apparatus 601 are immersed into the chemical liquid stored in the chemical liquid storage tank 602. Thereby, chemical liquid processing (cleaning processing or etching processing) is performed for the substrates W. When a predetermined time period elapses after the start of the immersion into the chemical liquid, the plural substrates W are pulled up from the chemical liquid storage tank 602 and transferred to the water storage tank 603. Next, the plural substrates Ware immersed into the water stored in the water storage tank 603. Thereby, rinse processing is performed for the substrates W. When a predetermined time period elapses after the start of the immersion into the water, the substrates W are pulled up from the water storage tank 603 and transferred to the EG storage tank 604.

By then controlling the lifter lifting unit 606 to move the lifter 605 from the retract position to the processing position, the plural substrates W held by the lifter 605 are immersed into the EG. By the immersion, the EG is supplied to the water remaining on front surfaces (the surfaces to be processed: the pattern forming surfaces in the present preferred embodiment) of the substrates W. Thereby, the water and the EG are mixed, and a water/EG mixture is supplied to upper surfaces of the substrates W.

The temperature of the EG stored in the EG storage tank 604 is regulated to be about 150° C. Thus, the water/EG mixture on the upper surfaces of the substrates W is heated (mixture heating step). As a result, the water contained in the water/EG mixture which has been supplied to the upper surfaces of the substrates W is boiled and the water is evaporated from the water/EG mixture. The liquid on the front surfaces of the substrates W accordingly contains only the EG. Thereby, the water on the front surfaces of the substrates W can be completely replaced with the EG. Therefore, pattern collapse of the front surfaces of the substrates W at the time of pulling the substrates W up from the EG can be suppressed.

The present inventors applied a water/EG mixture containing particles onto a silicon substrate and observed the drying step of the water/EG mixture on an upper surface of the substrate after that with an optical microscope. The present inventors conducted a test by using a water/EG mixture having an EG concentration of 2 weight % and a water/EG mixture having an EG concentration of 20 weight % as the water/EG mixture, and made observations of the respective mixtures. In this case, DIW was used as the water.

Immediately after the application, the particles gathered to a contact line in all cases. However, in the water/EG mixture having an EG concentration of 2 weight %, the particles were then moved in the direction of separating from the contact line over time. Meanwhile, in the water/EG mixture having an EG concentration of 20 weight %, the particles still gathered at the contact line after that.

With the water/EG mixture having an EG concentration of 2 weight %, a similar experiment was conducted under an IPA steam atmosphere. It was also observed in that case that the particles gathered at the contact line were moved in the direction of separating from the contact line after that.

The present inventors applied water containing particles, a mixture of IPA and water containing particles (hereinafter, referred to as “IPA/water mixture”), and a water/EG mixture containing particles onto silicon oxide film (thickness of 78 nm) chips respectively, rotated the respective chips by spin coating, and examined the amount of the particles after that. In this case, the amount of the particles provided in advance is the same for all the chips. DIW was used as the water, and EG concentration of the water/EG mixture was 10 weight %. IPA concentration in the IPA/water mixture is, for example, 5 weight %.

With the water containing the particles, a contamination range was 1.087%, whereas with the IPA/water mixture, a contamination range was 2.235%, and with the water/EG mixture, a contamination range was 0.007%.

This is considered because with the IPA/water mixture, the IPA was mainly evaporated at a gas-liquid-solid interface and as a result, Marangoni convection running toward the gas-liquid-solid interface was generated, and thereby, the particles were further urged to the gas-liquid-solid interface. As a result, particle performance was deteriorated.

Meanwhile, it is considered that with the water/EG mixture, the water was mainly evaporated at a gas-liquid-solid interface and as a result, Marangoni convection running in the direction of separating from the gas-liquid-solid interface was generated, and thereby, precipitation of the particles onto a chip front surface was suppressed.

FIG. 15 is an illustrative sectional view for describing an arrangement example of a processing unit 302 provided in a substrate processing apparatus 301 according to a third preferred embodiment of the present invention.

The processing unit 302 includes a box-shaped processing chamber 304, a spin chuck (substrate holding unit) 305 that holds a single substrate W in a horizontal posture in the processing chamber 304 and rotates the substrate W about the vertical rotational axis A2 passing through a center of the substrate W, a chemical liquid supplying unit 306 arranged to supply a chemical liquid to an upper surface of the substrate W which is held by the spin chuck 305, a water supplying unit (processing liquid supplying unit) 307 arranged to supply water serving as an example of a processing example to the upper surface of the substrate W which is held by the spin chuck 305, an EG supplying unit (low surface tension liquid supplying unit) 308 that supplies ethylene glycol (hereinafter, referred to as “EG”) serving as an example of a low surface tension liquid having the higher boiling point than that of the water (processing liquid) and lower surface tension than that of the water (processing liquid) to the upper surface (front surface) of the substrate W, a hot plate (heating unit) 309 disposed to face a lower surface of the substrate W which is held by the spin chuck 305, the hot plate being arranged to heat a water/EG mixture liquid film (hereinafter, referred to as “mixture liquid film”) 350 (see FIG. 18B, etc.) formed on the upper surface of the substrate W from the lower side via the substrate W, and a cylindrical processing cup 310 surrounding the spin chuck 305.

The processing chamber 304 includes a box-shaped partition wall 311, an FFU (fan filter unit) 312 serving as a blower unit that feeds clean air from an upper portion of the partition wall 311 to the inside of the partition wall 311 (corresponding to an interior of the processing chamber 304), and an exhaust apparatus (not shown) that exhausts gas in the processing chamber 304 from a lower portion of the partition wall 311.

The FFU 312 is disposed above the partition wall 311 and attached to a ceiling of the partition wall 311. The FFU 312 feeds clean air to the interior of the processing chamber 304 from the ceiling of the partition wall 311. The exhaust apparatus is connected to a bottom portion of the processing cup 310 via an exhaust duct 313 connected to an interior of the processing cup 310, and suctions the interior of the processing cup 310 from the bottom portion of the processing cup 310. A down flow (downward flow) is formed in the processing chamber 304 by the FFU 312 and the exhaust apparatus.

As the spin chuck 305, a clamping type chuck that clamps the substrate W in the horizontal direction to hold the substrate W horizontally is adopted. Specifically, the spin chuck 305 includes a vertically-extending cylindrical spin shaft 314, a disk-shaped spin base 315 attached to an upper end of the spin shaft 314 in a horizontal posture, plural (not less than three; for example, six) clamping pins 316 disposed at equal intervals in the spin base 315, and a spin motor 317 coupled to the spin shaft 314. The plural clamping pins 316 are disposed at suitable intervals, for example, at equal intervals on a circumference corresponding to an outer peripheral shape of the substrate W in a peripheral edge portion of an upper surface of the spin base 315. Each of the plural clamping pins 316 is an upward clamping pin (clamping pin whose lower portion is supported), to be displaced between a clamping position where the clamping pin is abutted with a peripheral edge portion of the substrate W to clamp the substrate W, and an open position further radially outward of the clamping position with respect to the substrate W. With the spin chuck 305, by abutting the clamping pins 316 with the peripheral edge portion of the substrate W to clamp the substrate, the substrate W is strongly held by the spin chuck 305. A drive mechanism (not shown) arranged to displace the clamping pins 316 is combined with the clamping pins 316. As clamping members, downward clamping pins (clamping pins whose upper portions are supported) may be adopted in place of the clamping pins 316.

The spin motor 317 is, for example, an electric motor. By transmitting rotational drive force from the spin motor 317 to the spin shaft 314, the substrate W held by the clamping pins 316 is rotated about the vertical rotation axis A2 passing through the center of the substrate W integrally with the spin base 315.

The hot plate 309 is formed in a disk shape having a horizontally flat front surface, for example, and has an outer diameter which is similar to an outer diameter of the substrate W. A circular upper surface of the hot plate 309 faces the lower surface (rear surface) of the substrate W held by the spin chuck 305. The hot plate 309 is disposed in a horizontal posture between the upper surface of the spin base 315 and the lower surface of the substrate W held by the spin chuck 305. The hot plate 309 is formed by using ceramics and silicon carbide (SiC), and a heater 318 is embedded inside. The entire hot plate 309 is warmed up by heating of the heater 318, so that the hot plate 309 functions to heat the substrate W. Over the entire upper surface of the hotplate 309, a heat generation amount per unit area of the upper surface in a state where the heater 318 is turned on is set to be uniform. The hot plate 309 is supported by a support rod 320 inserted through a through hole 319 which passes through the spin base 315 and the spin shaft 314 in the up and down direction in the vertical direction along the rotation axis A2 (in the thickness direction of the spin base 315). A lower end of the support rod 320 is fixed to a peripheral member below the spin chuck 305. The hotplate 309 is not coupled to the spin motor 317. Thus, even when the substrate W is rotated, the hot plate 309 is not rotated but remains stationary (in a non-rotation state).

A heater lifting unit 321 arranged to elevate and lower the hot plate 309 is combined with the support rod 320. The hot plate 309 is elevated and lowered while maintaining its horizontal posture by the heater lifting unit 321. The heater lifting unit 321 is formed by, for example, a ball screw or a motor. By drive of the heater lifting unit 321, the hot plate 309 is elevated and lowered between a lower position where the hot plate is separated from the lower surface of the substrate W held by the spin chuck 305 (see FIG. 18A, etc.), and an upper position where the hot plate comes close to the lower surface of the substrate W held by the spin chuck 305 with a minute gap (see FIG. 18B).

In a state where the upper surface of the hot plate 309 is placed at the upper position, the gap between the lower surface of the substrate W and the upper surface of the hot plate 309 is set to be, for example, about 0.3 mm. In a state where the upper surface of the hot plate 309 is placed at the lower position, the gap between the lower surface of the substrate W and the upper surface of the hot plate 309 is set to be, for example, about 10 mm. In such a way, the gap between the hot plate 309 and the substrate W can be changed.

The chemical liquid supplying unit 306 includes a chemical liquid nozzle 323. The chemical liquid nozzle 323 is, for example, a straight nozzle that discharges a liquid in a state of a continuous stream and is disposed fixedly above the spin chuck 305 with its discharge port directed at a central portion of the upper surface of the substrate W. A chemical liquid piping 324 to which chemical liquid from a chemical liquid supply source is supplied is connected to the chemical liquid nozzle 323. A chemical liquid valve 325 arranged to switch between supply/stop of supply of the chemical liquid from the chemical liquid nozzle 323 is interposed in an intermediate portion of the chemical liquid piping 324. When the chemical liquid valve 325 is opened, the chemical liquid of continuous stream supplied from the chemical liquid piping 324 to the chemical liquid nozzle 323 is discharged from the discharge port set in a lower end of the chemical liquid nozzle 323. When the chemical liquid valve 325 is closed, the supply of the chemical liquid from the chemical liquid piping 324 to the chemical liquid nozzle 323 is stopped.

Specific examples of the chemical liquid are an etching liquid and a cleaning liquid. More specifically, the chemical liquid may be hydrofluoric acid, SC1 (ammonia/hydrogen peroxide mixture), SC2 (hydrochloric acid/hydrogen peroxide mixture), ammonium fluoride, buffered hydrogen fluoride (mixture of hydrofluoric acid and ammonium fluoride), etc.

The water supplying unit 307 includes a water nozzle 326. The water nozzle 326 is, for example, a straight nozzle that discharges a liquid in a state of a continuous stream and is disposed fixedly above the spin chuck 305 with its discharge port directed at the central portion of the upper surface of the substrate W. A water piping 327 to which water from a water supply source is supplied is connected to the water nozzle 326. A water valve 328 arranged to switch between supply/stop of supply of the water from the water nozzle 326 is interposed in an intermediate portion of the water piping 327. When the water valve 328 is opened, the water of continuous stream supplied from the water piping 327 to the water nozzle 326 is discharged from the discharge port set in a lower end of the water nozzle 326. When the water valve 328 is closed, the supply of the water from the water piping 327 to the water nozzle 326 is stopped. The water is, for example, deionized water (DIW). However, the water of the present invention is not limited to DIW but may be any of carbonated water, electrolyzed ion water, hydrogen water, ozone water, and aqueous hydrochloric acid solution of dilute concentration (for example, of about 10 ppm to 100 ppm). The boiling point of the water (DIW) is 100° C. and surface tension is 72.75 at an ordinary temperature.

Each of the chemical liquid nozzle 323 and the water nozzle 326 does not need to be disposed fixedly with respect to the spin chuck 305. For example, a so-called scanning nozzle mode in which the nozzle is attached to an arm swingable in a horizontal plane above the spin chuck 305 and a liquid landing position of the processing liquid (the chemical liquid or the water) on the upper surface of the substrate W is scanned by swinging of the arm may be adopted.

The EG supplying unit 308 includes an EG nozzle 329 arranged to discharge the EG, a first nozzle arm 330 in which the EG nozzle 329 is attached to a tip portion, and a first nozzle moving unit 331 that moves the EG nozzle 329 by moving the first nozzle arm 330. The EG nozzle 329 is, for example, a straight nozzle that discharges the EG in a state of a continuous stream and is attached to the horizontally extending first nozzle arm 330 with its discharge port directed downward for example.

The EG supplying unit 308 also includes an EG piping 332 connected to the EG nozzle 329 to supply the EG from an EG supply source to the EG nozzle 329, an EG valve 333 arranged to switch supply/stop of supply of the EG from the EG nozzle 329, and a first flow rate regulation valve 334 arranged to adjust an opening degree of the EG piping 332 to regulate a flow rate of the EG discharged from the EG nozzle 329. The first flow rate regulation valve 334 includes a valve body (not shown) inside which a valve seat is provided, a valve element that opens and closes the valve seat, and an actuator (not shown) that moves the valve element between an open position and a close position. The same applies to the other flow rate regulation valves. The boiling point of the EG is 197.5° C. and surface tension is 47.3 at an ordinary temperature. That is, the EG is a liquid having the higher boiling point than that of the water and lower surface tension than that of the water.

As shown in FIG. 15, the processing cup 310 is disposed further outward of the substrate W held by the spin chuck 305 (in the direction of separating from the rotation axis A2). The processing cup 310 surrounds the spin base 315. When the processing liquid is supplied to the substrate W in a state where the spin chuck 305 rotates the substrate W, the processing liquid supplied to the substrate W is spun off to a periphery of the substrate W. When the processing liquid is supplied to the substrate W, an upper end portion 310a of the upward-opening processing cup 310 is disposed higher than the spin base 315. Therefore, the processing liquid discharged to the periphery of the substrate W such as the chemical liquid and the water is received by the processing cup 310. The processing liquid received by the processing cup 310 is fed to a recovery apparatus or a draining apparatus (not shown).

FIG. 16 is a block diagram for describing an electrical arrangement of a main portion of the substrate processing apparatus 301.

A controller 303 controls operations of the spin motor 317, the heater lifting unit 321, and the first nozzle moving unit 331, etc., in accordance with a predetermined program. The controller 303 also controls opening and closing operations, etc., of the chemical liquid valve 325, the water valve 328, the EG valve 333, and the first flow rate regulation valve 334, etc. Further, the controller 303 controls turning on/off of the heater 318.

FIG. 17 is a flowchart for describing an example of substrate processing performed by the substrate processing apparatus 301. FIGS. 18A to 18C are illustrative sectional views for describing states of a mixture forming step (S14 of FIG. 17), a mixture heating step (S15 of FIG. 17), and a drying step (S16 of FIG. 17). FIGS. 19A to 19F are illustrative sectional views showing states of the front surface of the substrate W in a rinsing step (S13 of FIG. 17), the mixture forming step (S14 of FIG. 17), the mixture heating step (S15 of FIG. 17), and the drying step S16 of FIG. 17). With reference to FIGS. 15 to 19F, the substrate processing will be described.

The unprocessed substrate W is carried into the processing unit 302 from the carrier C by the transfer robots IR, CR and carried into the interior of the processing chamber 304, the substrate W is delivered to the spin chuck 305 in a state where the front surface (the surface to be processed: the pattern forming surface in the present preferred embodiment) of the substrate is directed upward, and the substrate W is held by the spin chuck 305 (S11: substrate carry-in step (substrate holding step)). Before carrying in the substrate W, the EG nozzle 329 is retracted to a home position set on the side of the spin chuck 305. The hot plate 309 is disposed at the lower position where the hot plate is separated from the lower surface of the substrate W. At this time, the heater 318 is off.

After the transfer robot CR is retracted out of the processing unit 302, the controller 303 controls the spin motor 317 to start the rotation of the substrate W and accelerate the rotation to a predetermined liquid processing rotational speed (for example, about 800 rpm).

The controller 303 turns on the heater 318. Thereby, the heater 318 generates heat and a temperature of the upper surface of the hot plate 309 is increased to a predetermined fixed temperature. The front surface of the hot plate 309 is brought into a high temperature state by turning on the heater 318. However, since the hot plate 309 is disposed at the lower position, the substrate W is hardly warmed up by the heat from the hot plate 309.

Next, the controller 303 executes a chemical liquid step (Step S12). Specifically, after the rotational speed of the substrate W reaches the liquid processing speed, the controller 303 opens the chemical liquid valve 325. Thereby, the chemical liquid is supplied from the chemical liquid nozzle 323 toward the upper surface of the rotating substrate W. The supplied chemical liquid is spread over the entire surface of the substrate W by centrifugal force, and chemical liquid processing using the chemical liquid is performed for the substrate W. When a predetermined time period elapses after the start of the discharge of the chemical liquid, the controller 303 closes the chemical liquid valve 325 to stop the discharge of the chemical liquid from the chemical liquid nozzle 323.

Next, the controller 303 executes a rinsing step (Step S13). The rinsing step (S13) is a step of replacing the chemical liquid on the substrate W with the water to remove the chemical liquid from the top of the substrate W. Specifically, the controller 303 opens the water valve 328. Thereby, the water is supplied from the water nozzle 326 toward the upper surface of the rotating substrate W. The supplied water is spread over the entire surface of the substrate W by the centrifugal force. By the water, the chemical liquid attached to the top of the substrate W is washed away.

When a predetermined time period elapses after the start of the supply of the water, in a state where the entire upper surface of the substrate W is covered with the water, the controller 303 controls the spin motor 317 to stepwise reduce the rotational speed of the substrate W from the liquid processing speed to puddle speed (zero or a low rotational speed of about 40 rpm or less, for example, about 10 rpm). After that, the rotational speed of the substrate W is maintained at the puddle speed. Thereby, a water liquid film covering the entire upper surface of the substrate W is supported in a puddle shape on the upper surface of the substrate W. In this state, the centrifugal force acting on the water liquid film on the upper surface of the substrate W is smaller than the surface tension acting between the water and the upper surface of the substrate W, or the above-described centrifugal force is substantially balanced with the above-described surface tension. By the speed reduction of the substrate W, the centrifugal force acting on the water on the substrate W is weakened, and an amount of the water discharged from the top of the substrate W is reduced. Thereby, as shown in FIG. 19A, a puddle-shaped water liquid film 345 is formed on the upper surface of the substrate W. After that, the rotational speed of the substrate W is maintained at the puddle speed. The supply of the water to the substrate W is stopped after the formation of the water liquid film 345. However, after the formation of the puddle-shaped water liquid film, the supply of the water to the substrate W may be continued.

Next, the mixture forming step (Step S14 of FIG. 17) is executed.

Specifically, when a predetermined time period elapses after the speed reduction of the substrate W, the controller 303 controls the first nozzle moving unit 331 to move the EG nozzle 329 from the home position to a processing position above the substrate W. After that, the controller 303 opens the EG valve 333 to discharge the EG from the EG nozzle 329 toward the upper surface of the substrate W. Further, the controller 303 moves an EG supply position to the upper surface of the substrate W between the central portion and the peripheral edge portion. Thereby, the water supply position scans through the entire upper surface of the substrate W, and the EG is directly applied to the entire upper surface of the substrate W. For a while after the start of the discharge of the EG, the EG is not sufficiently spread inside the liquid film 345. As a result, as shown in FIG. 19B, the EG is accumulated in a surface layer portion of the liquid film 345, and the water is accumulated in a base layer portion of the liquid film 345. In this state, in the liquid film 345, a mixture of the water and the EG (hereinafter, referred to as “water/EG mixture”) is formed only in an intermediate portion between the surface layer portion and the base layer portion. After that, with the elapse of time, the EG is spread over the entire liquid film 345, and the entire water liquid film 345 is replaced with the water/EG mixture. That is, a mixture liquid film 350 is formed on the upper surface of the substrate W (see FIG. 18A and FIG. 19C).

Next, the controller 303 executes the mixture heating step (Step S15 of FIG. 17).

Specifically, the controller 303 controls the heater lifting unit 321 to elevate the hot plate 309 from the lower position (see FIG. 18A, etc.) to the upper position as shown in FIG. 18B. By disposing the hot plate 309 at the upper position, the substrate W is heated by heat radiation from the upper surface of the hot plate 309 that is at the upper position. Since the substrate W is heated to have a high temperature, the mixture liquid film 350 on the upper surface of the substrate W is also heated to have a high temperature which is substantially equal to the temperature of the substrate W. A temperature at which the mixture liquid film 350 is heated is set to be a predetermined high temperature (for example, about 150° C.) which is higher than the boiling point of the water and lower than the boiling point of the EG.

By heating the mixture liquid film 350, as shown in FIG. 19D, the water contained in the mixture liquid film 350 is boiled and the water is evaporated from the mixture liquid film 350. As a result, the water is completely removed from the mixture liquid film 350, and as shown in FIG. 19E, the liquid film contains only the EG. That is, an EG liquid film 351 is formed on the upper surface of the substrate W. Thereby, the water on the upper surface of the substrate W can be completely replaced with the EG.

When a predetermined time period elapses after the elevation of the hot plate 309, as shown in FIG. 18C, the controller 303 controls the heater lifting unit 321 to lower the position of the hot plate 309 from the upper position (see FIG. 18B) to the lower position. Thereby, the heating of the substrate W by the hot plate 309 is ended.

Next, the controller 303 controls the spin motor 317 to increase the rotational speed of the substrate W to spin-off drying speed (for example, 1,500 rpm) as shown in FIG. 18C. Thereby, the EG liquid film 351 on the upper surface of the substrate W is spun off and the substrate W is dried (spin drying, S16 of FIG. 17: drying step). In the drying step (S16), as shown in FIG. 19F, the EG is removed from between structures ST of a pattern PA. Since the EG has lower surface tension than that of the water, pattern collapse in the drying step (S16) can be suppressed.

When a predetermined time period elapses after the start of the drying step (S16), the controller 303 controls the spin motor 514 to stop the rotation of the spin chuck 305. The controller 303 also turns off the heater 318. After that, the transfer robot CR enters the processing unit 302 and carries the processed substrate W out of the processing unit 302 (Step S17 of FIG. 17). The substrate W is delivered from the transfer robot CR to the transfer robot IR, and housed in the carrier C by the transfer robot IR.

As described above, according to the third preferred embodiment, the EG is supplied to the water liquid film 345 of the substrate W. Thereby, the water and the EG are mixed, and the mixture liquid film 350 is formed on the upper surface of the substrate W. By heating the mixture liquid film 350, the water contained in the mixture liquid film 350 is evaporated. As a result, the water in the mixture liquid film 350 can be completely replaced with the EG.

The mixture liquid film 350 is formed by the supply of the EG and the water contained in the mixture liquid film 350 is evaporated, so that only the EG remains. Thus, speed to replace the water with the EG can be increased. Thereby, the water on the upper surface of the substrate W can be completely replaced with the EG in a short time. Therefore, the upper surface of the substrate W can be dried in a short time while reducing collapse of the pattern PA. Thereby, a drying time of the substrate W can be shortened and a use amount of the EG can be reduced.

In the mixture heating step (S15 of FIG. 17), the temperature at which the mixture liquid film 350 is heated is set to be the predetermined high temperature (for example, about 150° C.) which is higher than the boiling point of the water and lower than the boiling point of the EG. Therefore, although the EG in the water/EG mixture is hardly evaporated, the evaporation of the water in the water/EG mixture is facilitated. That is, only the water in the mixture liquid film 350 can be efficiently evaporated. Thereby, complete replacement by the low surface tension liquid can be realized in a further short time.

The temperature at which the mixture liquid film 350 is heated is lower than the boiling point of the EG. Thus, after the mixture heating step (S15 of FIG. 17), the EG liquid film having a predetermined thickness can be held on the upper surface of the substrate W.

By forming the puddle-shaped water liquid film 345 on the upper surface of the substrate W and supplying the EG to the water liquid film 345, the mixture liquid film 350 is formed on the upper surface of the substrate W. Thus, the discharge of the EG from the substrate W can be suppressed. Thereby, the use amount of the EG can be further reduced.

FIG. 20 is an illustrative sectional view for describing an arrangement example of a processing unit 502 provided in a substrate processing apparatus 501 according to a fourth preferred embodiment of the present invention.

In the fourth preferred embodiment, portions corresponding to the respective portions indicated in the third preferred embodiment will be indicated with the same reference symbols as in FIG. 15 to FIG. 19F and description thereof will be omitted.

The processing unit 502 is different from the processing unit 302 according to the third preferred embodiment in a first main point that a spin chuck (substrate holding unit) 505 is provided in place of the spin chuck 305. That is, the processing unit 302 does not include the hot plate 309.

The processing unit 502 is different from the processing unit 302 according to the third preferred embodiment in a second main point that the processing unit further includes a gas unit 537 arranged to supply gas to an upper surface of a substrate W held by the spin chuck 505.

As the spin chuck 505, a clamping type chuck that clamps the substrate W in the horizontal direction to hold the substrate W horizontally is adopted. Specifically, the spin chuck 505 includes a spin motor 514, a spin shaft 515 integrated with a drive shaft of the spin motor 514, and a disk-shaped spin base 516 substantially horizontally attached to an upper end of the spin shaft 515.

The spin base 516 includes a horizontal and circular upper surface 516a having an outer diameter which is larger than an outer diameter of the substrate W. Plural (not less than three; for example, six) clamping members 517 are disposed in a peripheral edge portion of the upper surface 516a. In the upper surface peripheral edge portion of the spin base 516, the plural clamping members 517 are disposed at suitable intervals, for example, at equal intervals on a circumference corresponding to an outer peripheral shape of the substrate W.

The gas unit 537 includes a gas nozzle 535 that discharges nitrogen gas serving as an example of inert gas toward the upper surface of the substrate W, a second nozzle arm 536 in which the gas nozzle 535 is attached to a tip portion, and a second nozzle moving unit 538 that moves the gas nozzle 535 by moving the second nozzle arm 536. The gas nozzle 535 is attached to the horizontally extending second nozzle arm 536 with its discharge port directed downward for example.

A gas piping 539 to which a high-temperature inert gas (higher than an ordinary temperature, for example, of 30 to 300° C.) from an inert gas supply source is supplied is connected to the gas nozzle 535. A gas valve 540 arranged to switch between supply/stop of supply of the inert gas from the gas nozzle 535 and a second flow rate regulation valve 541 arranged to adjust an opening degree of the gas piping 539 to regulate a flow rate of the inert gas discharged from the gas nozzle 535 are interposed in an intermediate portion of the gas piping 539. When the gas valve 540 is opened, the inert gas supplied from the gas piping 539 to the gas nozzle 535 is discharged from the discharge port. When the gas valve 540 is closed, the supply of the inert gas from the gas piping 539 to the gas nozzle 535 is stopped. The inert gas is not limited to nitrogen gas but may be CDA (clean dry air).

FIG. 21 is a block diagram for describing an electrical arrangement of a main portion of the substrate processing apparatus 501.

The controller 303 controls operations of the spin motor 514, the first and second nozzle moving units 331, 538, etc., in accordance with a predetermined program. Further, the controller 303 controls opening and closing operations, etc., of a chemical liquid valve 325, a water valve 328, an EG valve 333, the gas valve 540, the first and second flow rate regulation valves 334, 541, etc.

FIG. 22 is a flowchart for describing an example of substrate processing performed by the substrate processing apparatus 501. FIG. 23A to 23F are illustrative sectional views for describing states of a mixture forming step (S24 of FIG. 22), a liquid film removed region forming step (S25 of FIG. 22), and a liquid film removed region expanding step (S26 of FIG. 22). With reference to FIGS. 21 to 23F, the substrate processing performed by the substrate processing apparatus 501 will be described.

The unprocessed substrate W is carried into the interior of the processing chamber 504 by the transfer robots IR, CR, the substrate W is delivered to the spin chuck 505 in a state where the front surface (the surface to be processed: the pattern forming surface in the present preferred embodiment) of the substrate is directed upward, and the substrate W is held by the spin chuck 505 (S21: substrate carry-in step (substrate holding step)). Before carrying in the substrate W, an EG nozzle 329 and the gas nozzle 535 are retracted to home positions set on the side of the spin chuck 505.

After the transfer robot CR is retracted out of the processing unit 502, the controller 303 starts the rotation of the substrate W, and executes a chemical liquid step (Step S22), a rinsing step (Step S23), and the mixture forming step (Step S24) in order. The chemical liquid step (S22), the rinsing step (S23), and the mixture forming step (S24) are processes which are respectively similar to the chemical liquid step (Step S12), the rinsing step (Step S13), and the mixture forming step (Step S14) according to the third preferred embodiment. Thus, description thereof will be omitted.

In the mixture forming step (S24), a mixture liquid film 350 is formed on the upper surface of the substrate W (see FIG. 23A and FIG. 19C). Before the end of the mixture forming step (S24), the controller 303 controls the second nozzle moving unit 538 to dispose the gas nozzle 535 above the substrate W from the home position on the side of the spin chuck 505 as shown in FIG. 23B.

When a predetermined time period elapses after the start of the mixture forming step (S24), the controller 303 executes a drying step. In the drying step, the liquid film removed region forming step (S25), the liquid film removed region expanding step (S26), and an accelerating step (S27) are executed in this order. The liquid film removed region forming step (S25) is a step of forming a liquid film removed region 355 from which the mixture is removed in a central portion of the mixture liquid film 350. The liquid film removed region expanding step (S26) is a step of expanding the liquid film removed region 355 over the entire upper surface of the substrate W.

In the liquid film removed region forming step (S25), the controller 303 opens the gas valve 540 to discharge the inert gas from the gas nozzle 535 toward the central portion of the upper surface of the substrate W (gas blowing step), and controls the spin motor 514 to accelerate the substrate W to a predetermined hole making speed (for example, about 50 rpm) (high speed rotating step). By blowing the inert gas to the central portion of the mixture liquid film 350 on the upper surface of the substrate W, the water/EG mixture in the central portion of the mixture liquid film 350 is blown away and removed from the central portion of the upper surface of the substrate W by blowing pressure (gas pressure). By the rotational speed of the substrate W reaching the above-described hole making speed (for example, about 50 rpm), a relatively strong centrifugal force acts on the mixture liquid film 350 on the substrate W. Thereby, as shown in FIG. 23C, the circular liquid film removed region 355 is formed in the central portion of the upper surface of the substrate W. Although the hole making speed is set to be about 50 rpm, the hole making speed may be any rotational speed which is equal to or higher than the above-described speed. Next to the liquid film removed region forming step (S25), the liquid film removed region expanding step (S26) is executed.

In the liquid film removed region expanding step (S26), the controller 303 controls the spin motor 514 to increase the rotational speed of the substrate W to a predetermined first drying speed (for example, 1,000 rpm). In accordance with the increase in the rotational speed of the substrate W, the liquid film removed region 355 is expanded as shown in FIGS. 23D, 23E. By the expansion of the liquid film removed region 355, a gas-liquid-solid interface 360 of the mixture liquid film 350 between the liquid film removed region 355 and the upper surface of the substrate W is moved radially outward of the substrate W. As shown in FIG. 23F, by then expanding the liquid film removed region 355 over the entire substrate W, all the mixture liquid film 350 is discharged out of the substrate W.

After the liquid film removed region 355 is expanded over the entire upper surface of the substrate W, the liquid film removed region expanding step is ended. In accordance with the end of the liquid film removed region expanding step, the controller 303 closes the gas valve 540 to stop the discharge of the inert gas from the gas nozzle 535.

Next, the controller 303 executes the accelerating step (S27). Specifically, the controller 303 increases the rotational speed of the substrate W to about 1,500 rpm. Thereby, the upper surface of the substrate W is further dried.

When a predetermined time period elapses after the start of the accelerating step (S27), the controller 303 controls the spin motor 514 to stop the rotation of the spin chuck 305. After that, the transfer robot CR enters the processing unit 502 and carries the processed substrate W out of the processing unit 502 (Step S28). The substrate W is delivered from the transfer robot CR to the transfer robot IR, and housed in the carrier C by the transfer robot IR.

FIG. 23 is an expanded sectional view for describing an inner peripheral portion of the mixture liquid film 350.

After the formation of the liquid film removed region 355, the water having the low boiling point is mainly evaporated at the gas-liquid-solid interface 360. As a result, the EG concentration is increased. At this time, in an inner peripheral portion 370 of the mixture liquid film, such a concentration gradient that the EG concentration is lowered with distance from the gas-liquid-solid interface 360 is formed. In the present preferred embodiment, the EG concentration of the mixture liquid film 350 is fixed so that only the EG exists at the gas-liquid-solid interface 360 (that is, a supply amount of the EG in the mixture forming step (S24) is fixed). In this case, the water can be completely replaced with the EG at the gas-liquid-solid interface 360.

As described above, according to the present preferred embodiment, the EG is supplied to a water liquid film 345 of the substrate W. Thereby, the water and the EG are mixed, and the mixture liquid film 350 is formed on the upper surface of the substrate W.

The liquid film removed region 355 is formed in the mixture liquid film 350, and further, the liquid film removed region 355 is expanded until it covers the entire substrate W. On the upper surface of the substrate W, while the water/EG mixture is evaporated at the gas-liquid-solid interface 360 of the mixture liquid film 350, the liquid film removed region 355 is expanded. At the gas-liquid-solid interface 360, the water having the low boiling point is mainly evaporated. As a result, the EG concentration is increased. At this time, only the EG exists at the gas-liquid-solid interface 360, and in the inner peripheral portion 370 of the mixture liquid film, such a concentration gradient that the EG concentration is lowered with distance from the gas-liquid-solid interface 360 is formed. That is, at the gas-liquid-solid interface 360, the water can be completely replaced with the EG. It is considered that when the liquid is completely removed from between portions a pattern PA, surface tension of the liquid acts on the pattern PA. By completely replacing with the EG at the gas-liquid-solid interface 360, the surface tension acting on the pattern PA at the time of completely removing the liquid from the pattern PA can be suppressed to be low. Thus, collapse of the pattern PA can be suppressed.

The mixture liquid film 350 is formed by the supply of the EG and the water contained in the mixture liquid film 350 is evaporated, so that only the EG remains. Thus, speed to replace the water with the EG can be increased. Thereby, the water on the upper surface of the substrate W can be completely replaced with the EG in a short time. Therefore, the upper surface of the substrate W can be dried in a short time while reducing the collapse of the pattern PA. Thereby, a drying time of the substrate W can be shortened and a use amount of the EG can be reduced.

By supplying the high-temperature inert gas to the upper surface of the substrate W, the evaporation of the water at the gas-liquid-solid interface 360 of the mixture liquid film 350 can be facilitated. Thereby, complete replacement with the EG can be performed at the gas-liquid-solid interface 360 of the mixture liquid film 350.

By forming the puddle-shaped water liquid film 345 on the upper surface of the substrate W and supplying the EG to the water liquid film 345, the mixture liquid film 350 is formed on the upper surface of the substrate W. Thus, the discharge of the EG from the substrate W can be suppressed. Thereby, the use amount of the EG can be further reduced.

The present invention can also be applied to a batch type substrate processing apparatus. FIG. 25 is a schematic view for describing a general arrangement of a substrate processing apparatus 601 according to a fifth preferred embodiment of the present invention.

The substrate processing apparatus 601 is a batch type substrate processing apparatus that processes plural substrates W in batch processing. The substrate processing apparatus 601 includes a chemical liquid storage tank 602 that stores a chemical liquid, a water storage tank 603 that stores water, an EG storage tank 604 that stores an EG mixture, a lifter 605 that immerses the substrates W in the EG stored in the EG storage tank 604, and a lifter lifting unit 606 arranged to elevate and lower the lifter 605. The lifter 605 supports the plural substrates W in a vertical posture. The lifter lifting unit 606 elevates and lowers the lifter 605 between a processing position where the substrates W held by the lifter 605 are placed in the EG storage tank 604 (position shown by a solid line in FIG. 25) and a retract position where the substrates W held by the lifter 605 are placed above the EG storage tank 604 (position shown by a double chain line in FIG. 12).

A heater 607 that is immersed into the stored EG and heats the EG to adjust the temperature is provided in the EG storage tank 604. As the heater 607, a sheath heater can be taken as an example. A temperature meter (not shown) that measures a liquid temperature of the EG, a liquid amount sensor (not shown) that monitors a liquid amount in the EG storage tank 604, etc., are further provided in the EG storage tank 604. The liquid temperature of the EG stored in the EG storage tank 604 is regulated to be, for example, about 150° C.

In a series of processing in the substrate processing apparatus 601, the plural substrates W carried into a processing unit of the substrate processing apparatus 601 are immersed into the chemical liquid stored in the chemical liquid storage tank 602. Thereby, chemical liquid processing (cleaning processing or etching processing) is performed for the substrates W. When a predetermined time period elapses after the start of the immersion into the chemical liquid, the plural substrates W are pulled up from the chemical liquid storage tank 602 and transferred to the water storage tank 603. Next, the plural substrates W are immersed into the water stored in the water storage tank 603. Thereby, rinse processing is performed for the substrates W. When a predetermined time period elapses after the start of the immersion into the water, the substrates W are pulled up from the water storage tank 603 and transferred to the EG storage tank 604.

By then controlling the lifter lifting unit 606 to move the lifter 605 from the retract position to the processing position, the plural substrates W held by the lifter 605 are immersed into the EG. By the immersion, the EG is supplied to the water remaining on front surfaces (the surfaces to be processed: the pattern forming surfaces in the present preferred embodiment) of the substrates W. Thereby, the water and the EG are mixed, and a water/EG mixture is supplied to upper surfaces of the substrates W.

The temperature of the EG stored in the EG storage tank 604 is regulated to be about 150° C. Thus, the water/EG mixture on the upper surfaces of the substrates W is heated (mixture heating step). As a result, the water contained in the water/EG mixture which has been supplied to the upper surfaces of the substrates W is boiled and the water is evaporated from the water/EG mixture. The liquid on the front surfaces of the substrates W accordingly contains only the EG. Thereby, the water on the front surfaces of the substrates W can be completely replaced with the EG. Therefore, pattern collapse of the front surfaces of the substrates W at the time of pulling the substrates W up from the EG can be suppressed.

Although the five preferred embodiments of the present invention are described above, the present invention can also be implemented in further other modes.

For example, in the first preferred embodiment, the arrangement in which the puddle-shaped mixture liquid film 50 is formed on the upper surface of the substrate W by maintaining the rotational speed of the substrate W to the puddle speed and the liquid film removed region 55 is provided in the puddle-shaped mixture liquid film 50 is described. However, the mixture liquid film 50 is not limited to a puddle shape but the liquid film removed region 55 may be provided in a water liquid film which is being rotated at higher speed than the puddle speed.

The case where the inert gas is used as the gas supplied to the upper surface of the substrate W (gas discharged from the discharge port 35a) is described as an example. However, as the gas supplied to the upper surface (gas discharged from the discharge port 35a), steam of an organic solvent having lower surface tension than that of the water (for example, IPA (isopropyl alcohol) or HFE (hydrofluoroether)) can also be adopted.

In the first preferred embodiment, as the gas supplied to the upper surface of the substrate W (gas discharged from the discharge port 35a), mixture gas of the inert gas and the steam of the organic solvent (for example, mixture gas of N2 and the steam of the organic solvent) can also be adopted.

In the first preferred embodiment, use of the high-temperature gas as the gas supplied to the upper surface of the substrate W is described. However, normal-temperature gas may also be used.

In the first preferred embodiment, by both increasing the rotational speed of the substrate W and supplying the gas to the upper surface of the substrate W, the liquid film removed region 55 is formed in the mixture liquid film 50. However, the liquid film removed region 55 may be formed only by blowing the gas to the upper surface of the substrate W without increasing the rotational speed of the substrate W, or conversely, the liquid film removed region 55 may be formed only by increasing the rotational speed of the substrate W.

Further, in the first preferred embodiment, in the liquid film removed region expanding step, in order to expand the liquid film removed region 55 over the entire substrate W, the rotation of the substrate W is accelerated to the first drying speed. However, instead of the acceleration of the rotation of the substrate W or in addition to the acceleration of the rotation of the substrate W, by increasing a flow rate of blowing the gas to the upper surface of the substrate W, the liquid film removed region 55 may be expanded.

The gas unit 37 may include a facing member facing the upper surface (front surface) of the substrate W which is held by the spin chuck 5 in an integrally movable manner with the gas nozzle. The facing member may have a facing surface closely facing the front surface of the substrate W in a state where the discharge port 35a of the gas nozzle 35 comes close to the upper surface of the substrate W. In this case, a lateral and annular discharge port may separately be provided in the gas nozzle 35 having the downward discharge port 35a.

In a case where no gas is supplied to the upper surface of the substrate W, the gas unit 37 can also be eliminated.

In the first and second preferred embodiments, combination of the water and the EG is taken as an example as combination of the first liquid and the second liquid having the higher boiling point than that of the first liquid and lower surface tension than that of the first liquid. However, combination of IPA and HFE or combination of the water and PGMEA (propyleneglycol monomethyl ether acetate) can also be taken as an example as other combinations.

In the third preferred embodiment, the arrangement in which heating/non-heating of the substrate W is switched by elevating and lowering the hot plate 309 is described as an example. However, an arrangement in which heating/non-heating of the substrate W is switched by turning the heater 318 built in the hot plate 309 on and off may also be adopted.

In the third preferred embodiment, the arrangement in which the mixture liquid film 350 is heated from the lower side via the substrate W is described. However, instead of the arrangement, an arrangement in which the mixture liquid film 350 is heated from the upper side of the substrate W by a heater may also be adopted. In this case, in a case where the heater has a smaller diameter than that of the substrate W, the heater desirably irradiates the mixture liquid film 350 while moving along the upper surface of the substrate W. In a case where the heater has a diameter equal to or more than that of the substrate W, the heater may irradiate the mixture liquid film 350 in a state where the heater is disposed to face the substrate W above the substrate W.

In the third and fifth preferred embodiments, the temperature at which the mixture liquid film 350 is heated and the liquid temperature of the EG stored in the EG storage tank 604 are respectively set to be about 150° C. However, the temperatures can be set to be a predetermined high temperature within a range higher than the boiling point of the water and lower than the boiling point of the EG.

In the third and fourth preferred embodiments, by forming the puddle-shaped water liquid film 345 on the upper surface of the substrate W and supplying the EG to the water liquid film 345, the mixture liquid film 350 is formed on the upper surface of the substrate W. However, the mixture liquid film 350 may also be formed by supplying the EG to the upper surface of the substrate W which is being rotated at higher speed than the puddle speed (for example, the liquid processing speed).

The mixture liquid film 350 is formed on the upper surface of the substrate W by supplying the EG to the water liquid film 345 formed on the upper surface of the substrate W. However, the mixture liquid film 350 may also be formed by supplying the EG to the upper surface of the substrate W in a state where no water liquid film is formed on the upper surface of the substrate W (in a state where water droplets exist on the upper surface of the substrate W, or in a state where no liquid film or droplets exist on the front surface of the substrate but the water enters the pattern PA on the front surface of the substrate).

In the fourth preferred embodiment, the arrangement in which the puddle-shaped mixture liquid film 350 is formed on the upper surface of the substrate W and the liquid film removed region 355 is provided in the puddle-shaped mixture liquid film 350 is described. However, the mixture liquid film 350 is not limited to a puddle shape but the liquid film removed region 355 may be provided in a water liquid film which is being rotated at higher speed than the puddle speed.

In the fourth preferred embodiment, the case where the inert gas is used as the gas supplied to the upper surface of the substrate W is described as an example. However, as the gas, steam of an organic solvent having lower surface tension than that of the water (for example, IPA (isopropyl alcohol) or HFE (hydrofluoroether)) can also be adopted.

In the fourth preferred embodiment, as the gas supplied to the upper surface of the substrate W, mixture gas of the inert gas and the steam of the organic solvent can also be adopted.

In the fourth preferred embodiment, use of the high-temperature gas as the gas supplied to the upper surface of the substrate W is described. However, normal-temperature gas may also be used.

In the fourth preferred embodiment, by both increasing the rotational speed of the substrate W and supplying the gas to the upper surface of the substrate W, the liquid film removed region 355 is formed in the mixture liquid film 350. However, the liquid film removed region 355 may be formed only by blowing the gas to the upper surface of the substrate W without increasing the rotational speed of the substrate W, or conversely, the liquid film removed region 355 may be formed only by increasing the rotational speed of the substrate W.

Further, in the fourth preferred embodiment, in the liquid film removed region expanding step, in order to expand the liquid film removed region 355 over the entire substrate W, the rotation of the substrate W is accelerated to the first drying speed. However, instead of the acceleration of the rotation of the substrate W or in addition to the acceleration of the rotation of the substrate W, by increasing a flow rate of blowing the gas to the upper surface of the substrate W, the liquid film removed region 355 may be expanded.

The gas unit 537 may include a facing member facing the upper surface (front surface) of the substrate W which is held by the spin chuck 505 in an integrally movable manner with the gas nozzle. The facing member may have a facing surface closely facing the front surface of the substrate W in a state where the discharge port of the gas nozzle 535 comes close to the upper surface of the substrate W. In this case, a lateral and annular discharge port may separately be provided in the gas nozzle 535 having the downward discharge port.

In a case where no gas is supplied to the upper surface of the substrate W, the gas unit 537 can also be eliminated.

In the drying step of the fourth preferred embodiment, the accelerating step (S26) may be omitted.

In the third to fifth preferred embodiments, combination of the water and the EG is taken as an example as combination of the processing liquid and the low surface tension liquid having the higher boiling point than that of the processing liquid and lower surface tension than that of the processing liquid. However, combination of IPA and HEE or combination of the water and PGMEA (propyleneglycol monomethyl ether acetate) can also be taken as an example as other combinations.

In the above preferred embodiments, the case where the substrate processing apparatuses 1, 201, 301, 501, 601 are apparatuses that step the disk-shaped substrates W is described. However, the substrate processing apparatuses 1, 201, 301, 501, 601 may be apparatuses that step polygonal substrates such as glass substrates for liquid crystal display devices.

While the preferred embodiments of the present invention have been described in detail above, these are merely specific examples used to clarify the technical contents of the present invention, and the present invention should not be interpreted as being limited only to these specific examples, and the spirit and scope of the present invention shall be limited only by the appended claims.

The present application respectively corresponds to Japanese Patent Application No. 2015-161327 and Japanese Patent Application No. 2015-161328 filed on Aug. 18, 2015 in the Japan Patent Office, and the entire disclosure of these applications is incorporated herein by reference.

### DESCRIPTION OF THE REFERENCE NUMERALS

1: Substrate processing apparatus
3: Controller
5: Spin chuck (substrate holding unit)
8: Mixture supplying unit
14: Spin motor (substrate rotating unit)
201: Substrate processing apparatus
301: Substrate processing apparatus
303: Controller
305: Spin chuck (substrate holding unit)
307: Water supplying unit (processing liquid supplying unit)
308: EG supplying unit (low surface tension liquid supplying unit)
309: Hot plate (heating unit)
501: Substrate processing apparatus
505: Spin chuck (substrate holding unit)
601: Substrate processing apparatus
W: Substrate

1. A substrate processing method that processes a front surface of a substrate by using a processing liquid, comprising:
a mixture replacing step of replacing the processing liquid attached to the front surface of the substrate with a mixture of a first liquid and a second liquid having a higher boiling point than that of the first liquid and a lower surface tension than that of the first liquid; and
a mixture removing step of removing the mixture from the front surface of the substrate after the mixture replacing step.

2. The substrate processing method according to claim 1, further comprising:
a substrate holding step of horizontally holding the substrate, wherein
the mixture replacing step includes a liquid film forming step of forming a liquid film of the mixture covering an upper surface of the substrate, and
the mixture removing step includes:
a liquid film removed region forming step of forming a liquid film removed region in the liquid film of the mixture; and
a liquid film removed region expanding step of expanding the liquid film removed region toward an outer periphery of the substrate.

3. The substrate processing method according to claim 2, further comprising:
a puddling step of bringing the substrate into a stationary state or rotating the substrate about the rotation axis at a puddle speed in parallel with the liquid film forming step.

4. The substrate processing method according to claim 2, wherein the liquid film removed region forming step includes a gas blowing step of blowing gas to the upper surface of the substrate.

5. The substrate processing method according to claim 4, wherein the gas includes a high-temperature gas having a higher temperature than an ordinary temperature.

6. The substrate processing method according to claim 2, wherein the liquid film removed region expanding step includes a high speed rotating step of rotating the substrate at higher speed than that of the time of the liquid film forming step.

7. The substrate processing method according to claim 1, wherein the first liquid includes water, and
the second liquid includes ethylene glycol.

8. A substrate processing apparatus comprising:
a substrate holding unit that horizontally holds a substrate;
a mixture supplying unit that supplies a mixture of a first liquid and a second liquid having a higher boiling point than that of the first liquid and a lower surface tension than that of the first liquid to an upper surface of the substrate; and
a controller that controls at least the mixture supplying unit, wherein the controller executes a liquid film forming step of forming a liquid film of the mixture covering the upper surface of the substrate, a liquid film removed region forming step of forming a liquid film removed region in the liquid film of the mixture, and a liquid film removed region expanding step of expanding the liquid film removed region toward an outer periphery of the substrate.

9. A substrate processing method that processes a front surface of a substrate by using a processing liquid, comprising:
a mixture forming step of, by supplying a low surface tension liquid having a higher boiling point than that of the processing liquid and a lower surface tension than that of the processing liquid to the front surface of the substrate where the processing liquid remains, forming a mixture of the remaining processing liquid and the low surface tension liquid on the front surface of the substrate;
a replacing step of evaporating the processing liquid from the mixture supplied to the front surface of the substrate and replacing at least the mixture on an interface between the mixture and the front surface of the substrate with the low surface tension liquid; and
a drying step of removing the low surface tension liquid from the front surface of the substrate and drying the front surface of the substrate.

10. The substrate processing method according to claim 9, wherein the replacing step includes a mixture heating step of heating the mixture in order to evaporate the processing liquid contained in the mixture.

11. The substrate processing method according to claim 10, further comprising:
a substrate holding step of horizontally holding the substrate, wherein
the mixture forming step includes a step of forming a liquid film of the mixture covering an upper surface of the substrate, and
the mixture heating step includes a step of heating the liquid film of the mixture.

12. The substrate processing method according to claim 10, wherein the mixture heating step is to heat the mixture at a predetermined high temperature which is higher than the boiling point of the processing liquid and lower than the boiling point of the low surface tension liquid.

13. The substrate processing method according to claim 9, further comprising:
a substrate holding step of horizontally holding the substrate, wherein
the mixture forming step includes a step of forming a liquid film of the mixture covering an upper surface of the substrate, and
the replacing step includes:
a liquid film removed region forming step of forming a liquid film removed region in the liquid film of the mixture; and
a liquid film removed region expanding step of expanding the liquid film removed region toward an outer periphery of the substrate.

14. The substrate processing method according to claim 13, further comprising:
a puddling step of bringing the substrate into a stationary state or rotating the substrate about the rotation axis at a puddle speed in parallel with the mixture liquid film forming step.

15. The substrate processing method according to claim 13, wherein the liquid film removed region forming step includes a gas blowing step of blowing gas to the upper surface of the substrate.

16. The substrate processing method according to claim 13, wherein the liquid film removed region expanding step includes a high speed rotating step of rotating the substrate at higher speed than that of the time of the mixture liquid film forming step.

17. The substrate processing method according to claim 16, wherein the gas includes a high-temperature gas having a higher temperature than an ordinary temperature.

18. The substrate processing method according to claim 17, wherein the processing liquid includes water, and
the low surface tension liquid includes ethylene glycol.

19. A substrate processing apparatus comprising:
a substrate holding unit arranged to horizontally hold a substrate;
a processing liquid supplying unit arranged to supply a processing liquid to an upper surface of the substrate;
a low surface tension liquid supplying unit arranged to supply a low surface tension liquid having a higher boiling point than that of the processing liquid and a lower surface tension than that of the processing liquid to the upper surface of the substrate; and
a controller that executes a mixture liquid film forming step of, by controlling the processing liquid supplying unit and the low surface tension liquid supplying unit to supply the low surface tension liquid to the upper surface of the substrate where the processing liquid remains, forming a liquid film of a mixture of the remaining processing liquid and the low surface tension liquid to cover the upper surface of the substrate, a replacing step of evaporating the processing liquid from the liquid film of the mixture formed on the upper surface of the substrate and replacing the mixture on an interface between the liquid film of the mixture and the upper surface of the substrate with the low surface tension liquid, and a drying step of removing the low surface tension liquid from the upper surface of the substrate and drying the upper surface of the substrate.

20. The substrate processing apparatus according to claim 19, further comprising:
a heating unit arranged to heat the liquid film of the mixture which is formed on the upper surface, wherein
an object to be controlled by the controller includes the heating unit, and
the controller executes the replacing step by controlling the heating unit to heat the liquid film of the mixture.
